(19) United States
(12) Patent Application Publication
(10) Pub. No.: US 2011/0133780 A1
(43) Pub. Date: Jun. 9, 2011

(54) HIGH PERFORMANCE LOW POWER OUTPUT DRIVERS

(76) Inventor: Jeng-Jye Shau, Palo Alto, CA (US)

(21) Appl. No.: 12/699,633

(22) Filed: Feb. 3, 2010

Related U.S. Application Data
(63) Continuation-in-part of application No. 12/631,797, filed on Dec. 4, 2009.

(51) Int. Cl. H03K 19/0175

(52) U.S. Cl. 326/87

(57) ABSTRACT

Long existing performance, noise, and power consumption problems of known output drivers are solved by using n-channel transistors as pull up transistors and/or p-channel transistors as pull down transistors for high performance output drivers. In combination with RC termination circuits, output drivers of the present invention can be fully compatible with HSTL, SSTL, GTL, BTL, SATA, PCIe, LVDS, MIPI, MDDI or other partial voltage interfaces.

### BACKGROUND OF THE INVENTION

The present invention relates to output drivers for integrated circuits (IC), and more particularly to low power, high performance output drivers capable of driving multiple-level switching and/or partial-voltage signals.

In this patent application, an “output driver” is defined as the last-stage circuit in an IC that drives output signals from the IC to external components. In most ICs, output drivers are manufactured and designed differently than the other circuitry internal to the IC. In this regard, general purpose drivers internal to an IC are not “output drivers.” A “high performance output driver” is a high performance last-stage circuit that drives high performance switching signals from an IC at a rate of hundreds of thousands of cycles per second or higher. A “pull up transistor” in an output driver is defined as a transistor that couples the output of the output driver to the higher of two reference voltages. A pull up transistor thus “pulls” the output “up” towards the higher reference voltage when the transistor is on. A “pull down transistor” in an output driver that couples the output of the output driver to the lower of two reference voltages. A pull down transistor thus “pulls” the output “down” towards the lower reference voltage when the transistor is on. An “n-channel transistor” is defined as a transistor that uses electrons as the majority charge carrier and includes an NMOS field effect transistor. A “p-channel transistor” is defined as a transistor that uses holes as the majority charge carrier and includes a PMOS field effect transistor. One transistor can comprise many legs of transistors connected in parallel. A “partial-voltage signal” is a signal with quiescent state voltage level lower than the pull up voltage supply of the output driver driving the signal, and higher than the pull down voltage supply of the output driver. “Quiescent state”, which is often called “steady state”, means the state when the output signal remains stable. A “partial voltage interface” is an integrated circuit interface that communicates with partial voltage signals, which is also referred to herein as a “small signal interface.”

Today, IC technologies involve patterning features having dimensions in the nanometer (nm) range, which allows for very fast transistor switching speeds. For example, current art 32 nm logic technologies provide transistors with switching times in the picosecond (ps)—i.e., 10⁻¹² seconds—regime. Consequently, it has become a routine practice to design logic circuits internal to the IC that are capable of executing billions, or even trillions, of operations per second. To fully exploit such fast core circuits require high performance output drivers. Otherwise, input/output (I/O) bandwidth would become the performance bottleneck in high performance systems. It is therefore highly desirable to provide methods to improve the performance of I/O circuits, and in particular output drivers, for integrated circuits.

The performance of output drivers has significant impacts to overall system performance. The most common output drivers used by prior art ICs are CMOS (complementary metal-oxide-semiconductor) drivers. CMOS drivers consume little power at quiescent state, and provide signals that approach the full amplitude of the I/O voltage supply sources. However, noise related switching problems limits CMOS drivers in supporting high performance interfaces. It is therefore highly desirable to provide output drivers that can avoid switching noise problems to support high performance operations.

A common method used to improve the performance of CMOS output drivers is to reduce the amplitude of the output signals by introducing one or more termination resistor(s) to each signal line. The termination resistor is typically connected to a reference voltage (VREF) equal to half (or a fraction) of the I/O voltage supply source. We also use the term “termination voltage” (VTT) when the termination resistor also serves an anti-reflection purpose. The same reference voltage is typically also used for input data sensing. This is called a “high-speed transceiver logic” (HSTL) interface when it is used by high end SRAM (static random access memory). A nearly identical approach used by used by DRAM (dynamic random access memory) is called a “stub series terminated logic” (SSTL) interface. A DRAM “double data rate version 2” (DDR2) SSTL interface operates at between 400 to 800 million bits per second. A DRAM “double data rate version 3” (DDR3) SSTL interface operates between 800 to 1600 million bits per second. A partial voltage interface utilized for logic circuits is called “Gunning Transceiver Logic” (GTL). GTL typically has a voltage swing of between 0.4 volts and 1.2 volts. The maximum signalling frequency for GTL was originally specified to be 100 MHz. However, present day ICs typically use upgraded GTL interfaces (such as GTL+) operating at even higher frequencies. For example, present day Intel microprocessors and chip sets use GTL at a frequency of 1.6 GHz. Another method, similar to GTL, is called “Backplane Transceiver Logic” (BTL) that is commonly used for communication integrated circuits. This type of methods is called “partial voltage interfaces” or “small amplitude interfaces” (SAI) in our discussions because they all use signal amplitudes that are a fraction of full power supply voltages. SAI effectively improved interface performance relative to conventional CMOS interfaces. However, conventional SAI drivers consume power even when they are not switching data, and they still suffer from most of the noise problems common to conventional CMOS drivers. It is therefore highly desirable to provide further improvements in performance relative to conventional SAI while consuming little power at quiescent state.

Wireless devices such as cellular phones have progressed at an explosive pace. Battery powered portable devices always benefit from decreased power consumption. At the same time, the demand for higher performance increases dramatically with each generation of wireless products. For example, cellular phones used to have no or very simple displays; now they commonly implement colored liquid crystal display (LCD) at high resolution. A current art LCD output driver can send out 132 RGB signals (totaling 396 digital-to-analog converter output signals) with 6 bit accuracy (64 levels) switching at around 12 KHZ. Such IC devices require high accuracy, low power, digital-to-analog (D/A) output drivers. Most prior art digital-to-analog converters use operational amplifiers with negative feedback to provide high accuracy output signals, but operational amplifiers typically consume a lot of power and have poor switching speed. U.S. Pat. No. 6,124,997 discloses an LCD driver design that does not use operational amplifiers; instead, the method involves pre-charging each output line before driving new data. The pre-charge operation will consume power whether the data is changed or not. Because Tsuchi only uses pull down drivers, the method is sensitive to noises that cause the output signal to drop below targeted voltages. It is therefore highly desirable to provide low power output drivers that can support high accuracy switching signals.

U.S. Pat. No. 4,816,705 (the '705 patent) discloses methods to make the output voltages of Bi-MIS logic circuits almost equal to that of the voltage supply sources. These drivers drive internal signals so they are not output drivers. The non-inverting buffers disclosed in the '705 patent use n-channel pull up transistors and p-channel pull down transistors as the biasing circuits for the drivers to increase the range of output voltages; but these transistors are not used to drive the outputs. The '705 patent also discloses methods to make the output voltages of Bi-MIS logic circuits almost equal to that of the voltage supply sources. The patent discloses special kinds of output drivers that support multiple-level switching partial-voltage signals.

U.S. Pat. No. 6,958,632 (the '632 patent) discloses voltage follower buffers to reduce power line noise induced timing uncertainty, called “jitter”, on internal signal buffers such as clock buffers. The output of the buffer is driven by an n-channel pull up transistor that can pull the output up to Vcc−Vtn (where Vtn is the threshold voltage of the n-channel transistor), a p-channel pull down transistor that can pull the output up to Vss+Vtp (where Vtp is the threshold voltage of the p-channel transistor), and a CMOS buffer that drives the output to full scale voltages Vcc or Vss. These drivers are internal signal buffers, not output drivers. The '632 patent also discloses methods to make the output voltages of the buffers equal to that of the voltage supply sources instead of multiple-level switching partial-voltage signals.

U.S. Pat. No. 6,560,290 discloses CMOS output drivers and on-chip termination for high speed data communication such as for an Ethernet transmitter/receiver. N-channel pull up transistors and p-channel pull down transistors are used in the on-chip termination circuits but not in the output drivers. The function of a termination circuit is to imitate the functions of resistors for impedance matching purposes, and to hold the steady-state voltage of the signal bus near half that of the supply voltage.

U.S. Pat. No. 6,384,658 by Jex discloses circuits to generate non-inverting and inverting clock signals with balanced timing. Those circuits are clock signal generators, not output drivers. In Jex, n-channel pull up transistors and p-channel pull down transistors are used in the input stages of the clock circuits in order to balance the timing of the two inverted output signals. These transistors have no relationship to output drivers.

This patent application provides further understandings on the termination circuits and output drivers of the present invention.

### SUMMARY OF THE PREFERRED EMBODIMENTS

One of the primary objectives of the preferred embodiments is, therefore, to provide output drivers that reduce power consumption at quiescent state. Another primary objective of the preferred embodiments is to provide output drivers that can switch between multiple levels of high accuracy output voltages while consuming less power. Another objective is to support small amplitude interface protocols without using termination resistors. Another objective is to provide termination circuits working with output drivers of the present invention to consume less power. Another objective is to reduce the cost of output drivers that drive memory interfaces such as HSTL or SSTL interfaces. Another objective is to improve the fan out of partial voltage output drivers. These and other objectives are achieved by using output drivers comprising n-channel pull up transistors and/or p-channel pull down transistors biased with proper gate voltages, and/or using RC termination circuits.

While the novel features of the invention are set forth with particularly in the appended claims, the invention, both as to organization and content, will be better understood and appreciated, along with other objects and features thereof, from the following detailed description taken in conjunction with the drawings.

### BRIEF DESCRIPTION OF THE DRAWINGS

FIGS. 1(a, b) illustrate the structures and operational principles of known CMOS drivers;

FIGS. 2(a, b) illustrate the structures and operational principles of known SAI drivers;

FIGS. 3(a, b) illustrate the structures and operational principles of a basic output driver of the present invention;

FIG. 3(c) shows the current-voltage relationship of the output driver shown in FIG. 3(a);

FIGS. 3(d-i) are schematic diagrams showing various output driver designs of the present invention;

FIGS. 4(a-f) are schematic diagrams showing different gate voltage generation circuits to support output drivers of the present invention;

FIGS. 5(a-c) illustrate methods to use native transistors in output drivers of the present invention;

FIG. 6 shows an output driver of the present invention supporting multiple-level-switching output voltages;

FIGS. 7(a-d) are examples of cost efficient output drivers of the present invention;

FIGS. 8(a-b) illustrate the structures and operation principles of known differential signal drivers;

FIGS. 9(a-d) are examples of differential signal drivers of the present invention;

FIGS. 10(a-e) show examples of prior art partial voltage output drivers driving transmission lines terminated with resistors;

FIGS. 11(a-j) show examples of drivers and termination circuits of the present invention; and

FIGS. 12(a-k) illustrate various implementations of RC termination circuits supporting output drivers of the present invention.

### DETAILED DESCRIPTION OF THE PREFERRED EMBODIMENTS

The operation principles of prior art output drivers are first discussed to facilitate a clear understanding of the present invention.

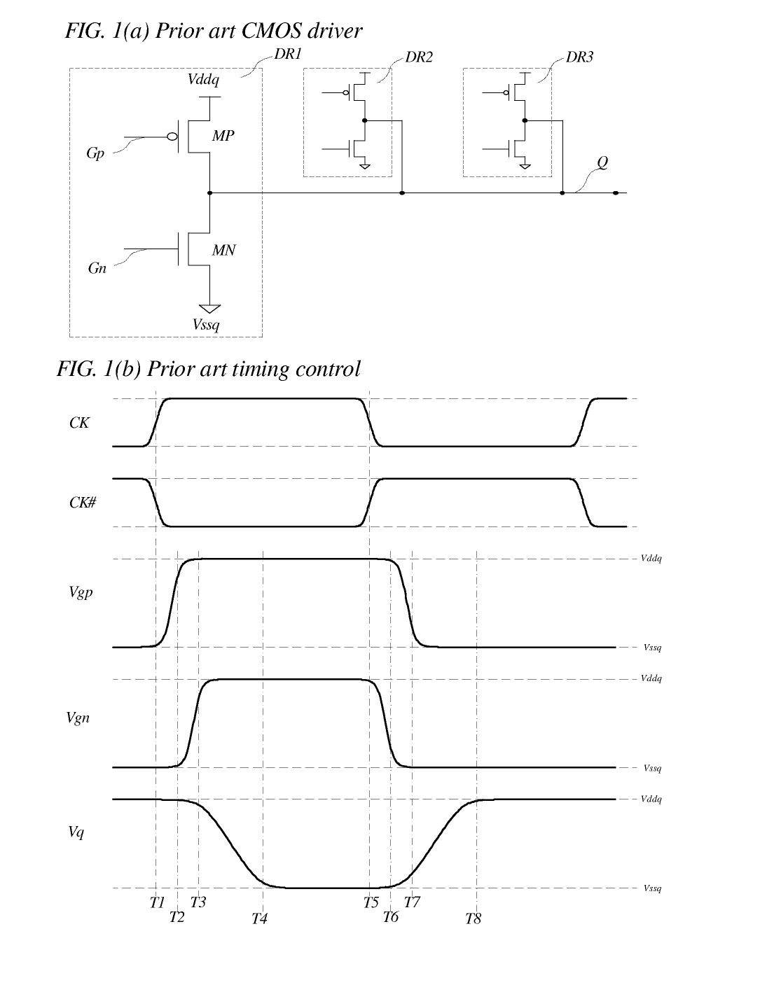

FIG. 1(a) is a schematic diagram showing the basic elements of a prior art CMOS output driver (DR1). This prior art output driver (DR1) comprises a p-channel pull up transistor (MP) and an n-channel pull down transistor (MN). One transistor shown in a schematic diagram can comprise many legs of transistors connected in parallel.

For the output driver (DR1) in FIG. 1(a), the source electrode of the p-channel pull up transistor (MP) is connected to an upper voltage supply line at voltage Vddq. The source electrode of the n-channel pull down transistor (MN) is connected to a lower voltage supply line at voltage Vssq, where Vssq<Vddq and is usually at ground voltage. The drain electrode of the p-channel pull up transistor and the drain electrode of the n-channel pull down transistor are both connected to an external signal line (Q). An “external signal line” is defined as a signal line that provides an external input signal to and/or receives an output signal from an IC chip. The gate electrode (Gp) of the p-channel pull up transistor (MP) is driven at a gate voltage Vgp, and the gate electrode (Gn) of the n-channel pull down transistor (MN) is driven at a gate voltage Vgn. More output drivers (DR2, DR3) from different circuits can be connected to the same external signal line (Q).

Although the structure of this CMOS output driver (DR1) may appear to be a simple CMOS inverter, the requirement that the output driver supply large electrical currents to heavy electrical loads necessitates special designs for these output drivers. Consequently, the design methods and the structures of CMOS output drivers are typically different from those of internal drivers.

FIG. 1(b) shows example timing control waveforms to illustrate the operational principles of the prior art CMOS driver in FIG. 1(a). In this example, the timing is synchronized by a pair of clock signals (CK, CK #). The clock signal (CK) rises at time T1, while the complementary clock signal (CK #) rises at half cycle time T5, as illustrated in FIG. 1(b). Before time T1, Vgp=Vgn=Vssq and the output voltage (Vq) on the external signal line (Q) is held at voltage Vddq. The rising edge of clock signal (CK) at time T1 triggers the output driver to send out the next data. However, for practical as well as theoretical reasons, the output drivers in FIG. 1(a) cannot adjust their output voltage instantaneously. One reason is that it is very important that both output transistors (MP, MN) are not partially turned on at the same time; otherwise a large current would flow through MP and MN from Vddq to Vssq, causing severe noise problems. It is therefore a common practice to turn off MP by pulling its gate voltage (Vgp) toward Vddq starting at T1 before pulling up the gate voltage of MN (Vgn) toward Vddq at a latter time T2, as shown by FIG. 1(b). This method effectively reduces noise problems but introduces an additional delay (T2−T1) that slows the response time of the output driver. We will call this delay time the “flow through current prevention delay time” in the following discussion. After T2, the p-channel pull up transistor (MP) is turned off and the n-channel pull down transistor (MN) is turned on to pull Vq down to Vssq as shown by the waveforms in FIG. 1(b). During this time, a large current (called “switching current”) flows from Vssq through MN to Q, causing large noise on Vssq and Q. In the mean time, the switching gate voltages (Vgp, Vgn) also cause capacitance induced coupling noises during the switching events between T1 and T4; this coupling noise is of opposite sign than the output signal, so it slows down the output signal. The pull down switching rate of the output voltage increases with increasing channel currents of the pull down n-channel transistor (MN), but the switching noises and coupling noises also increase with increasing driving power. This causes a dilemma that precludes prior art CMOS output drivers from both achieving a high switching rate and also conserving signal integrity. Due to noise considerations, typical circuit designs compromise by tolerating a slow switching rate on the output signal (Vq). For example, typical prior art output drivers adjust the switching rate at around 1 volt per nanosecond, which is about two orders of magnitude slower than that of IC core circuits. Using faster transistors is not a viable solution because the resulting noise destroys signal integrity. This is one of the reasons that interface delay time often becomes a performance bottleneck for high performance ICs. When the output voltage (Vq) completely reaches Vssq after time T4, the driver consumes little power and the system is finally stable.

For a double data rate (DDR) protocol, the rising edge of the complementary clock signal (CK #) at time T5 triggers the output driver to send out another data. FIG. 1(b) illustrates the procedures to switch the output voltage from Vssq back to Vddq after time T5. To the prevent flow through current noise problem, we still need to turn off MN by pulling Vgn toward Vssq starting at an earlier time (T5) before pulling Vgp toward Vssq at a latter time (T6). This method effectively reduces noise problems but introduces additional delay (T6−T5). After T6, the n-channel transistor (MN) is turned off and the p-channel transistor (MP) starts to pull output voltage (Vq) up to Vddq as shown by the waveforms in FIG. 1(b). During this time, a large switching current flows from Vddq through MP to Q, causing large noise on Vddq and Q. In the mean time, the switching gate voltages (Vgp, Vgn) also cause capacitance induced coupling noises during the switching events between T5 and T8. The pull up switching rate is again limited by electrical circuit noise. Again, typical output driver circuit designs accommodate these noise considerations by tolerating a slow switching rate on the output signal (Vq). When the output voltage completely reaches Vddq after time T8, the output driver (DR1) consumes little power and the system is stable.

We can turn off this output driver (DR1) by setting Vgp=Vddq and Vgn=Vssq so that the output driver is in a high impedance state to allow other output drivers (DR2, DR3) to drive the external signal line (Q).

The major advantages for prior art CMOS drivers are that they consume little power at quiescent state, and they provide nearly full scale voltage outputs from the voltage supply sources (e.g., Vddq, Vssq) that represent digital signals. These advantages make CMOS output drivers the most popular output drivers for integrated circuits. However, CMOS output drivers typically consume large amounts of power and cause severe noise problems during switching. The switching noise problems and the “flow through current prevention delay time” limit the applications of CMOS output drivers in high performance applications.

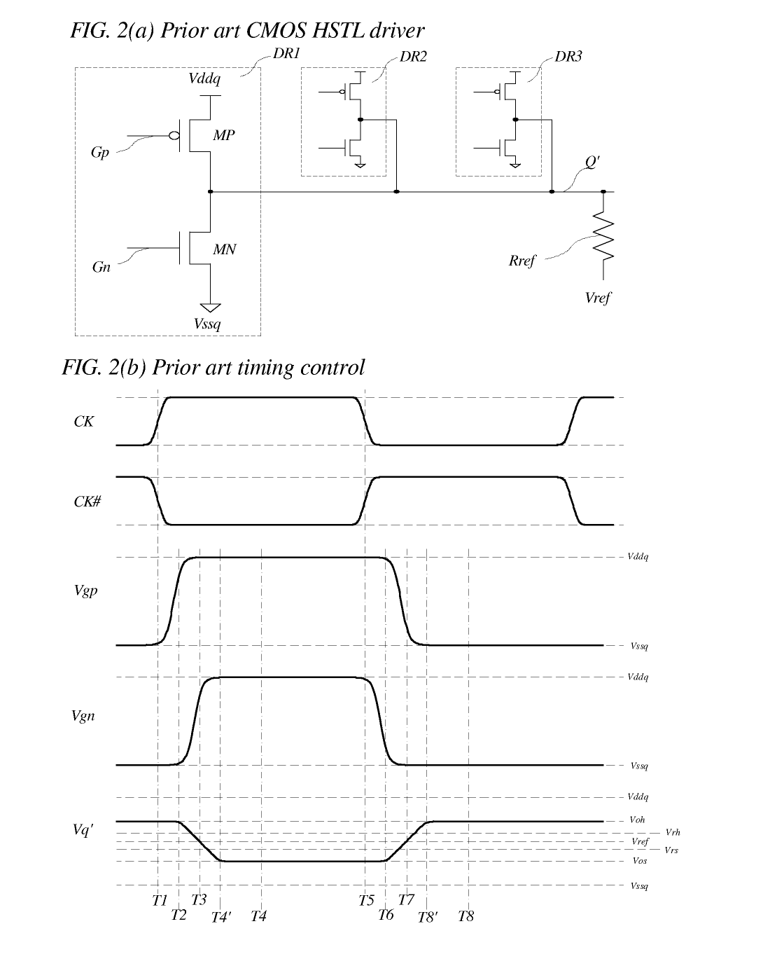

FIGS. 2(a,b) illustrate the most popular prior art method used to improve the performance of CMOS output drivers. This method employs a “high-speed transceiver logic” (HSTL) interface when used as a high end SRAM (static random access memory) interface. A nearly identical method employs a “stub series terminated logic” (SSTL) interface when used as a DRAM (dynamic random access memory) interface. Similar methods applied in logic circuitry are referred to as “Gunning Transceiver Logic” (GTL) or “Backplane Transceiver Logic” (BTL), which are commonly used for microprocessors, graphic controller, chipsets, communication chips or other integrated circuits. We will call those types of methods “small amplitude interfaces” (SAI) in our discussions. The major difference between the CMOS interface shown in FIG. 1(a) and the SAI shown in FIG. 2(a) is that a termination resistor (Rref), or an equivalent circuit, is added to the external signal line (Q′). A typical value of Rref is 50 ohms. This termination resistor (Rref) is connected to a reference voltage (Vref) typically adjusted to the middle of the voltage supply source as Vref=(Vddq+Vssq)/2. Prior art SAI still using the same CMOS output drivers to support their operation as illustrated by the schematic diagram in FIG. 2(a). Since the pull up and pull down transistors (MN, MP) need to fight with the termination resistor (Rref), the output voltage (Vq′) switches within a smaller range between Voh and Vos as illustrated in FIG. 2(b). We will refer to Voh as “SAI upper voltage”, and Vos as “SAI lower voltage”. Typically, Voh is about [Vref+(Vddq−Vssq)/4], and Vos is about [Vref−(Vddq−Vssq)/4]. A logic state ‘1’ is typically characterized as a voltage higher than a voltage Vrh, which is approximately [Vref+(Vddq−Vssq)/8]. A logic state ‘0’ is typically characterized as a voltage lower than a voltage Vrs, which is approximately [Vref−(Vddq−Vssq)/8]. For example, when Vddq=1.8 volts and Vssq=0 volts, the SSTL specification requires that Vref is 0.9 volts, Voh is approximately 1.4 volts, Vos is approximately 0.4 volts, Vrh is approximately 1.1 volts, and Vrs is approximately 0.7 volts.

FIG. 2(b) shows example timing waveforms to illustrate the operation principles of SAI in comparison with the traditional CMOS interface waveforms in FIG. 1(b). Similar to the previous example, the output driver (DR1) gate voltages at Vgp and Vgn are Vssq before time T1. The terminal resistor acts as a voltage divider with the p-channel pull up transistor (MP) so that the output voltage (Vq′) is held at SAI upper voltage (Voh) instead of Vddq as shown in FIG. 1(b). The rising edge of clock signal (CK) at time T1 triggers the output driver to send out the next data. Before switching the output voltage (Vq′) on Q′, it is still important to avoid turning on both output transistors (MP, MN) simultaneously. Thus, typically MP is turned off by pulling the gate voltage of MP (Vgp) toward Vddq at T1 before turning on MN by pulling up the gate voltage of MN (Vgn) toward Vddq at a latter time T2, as shown by FIG. 2(b). After T2, the p-channel transistor (MP) is turned off and the n-channel transistor (MN) is turned on to pull down output voltage (Vq′), as shown by the waveforms in FIG. 2(b). During this time, there is still a switching current and still coupling voltage induced noise problems. The difference is that Vq′ is pulled to SAI lower voltage (Vos) instead of Vssq because the pull down n-channel transistor (MN) acts as a voltage divider with the termination resistor (Rref). For an SAI, the output voltage (Vq′) switches between Voh and Vos, instead of Vddq and Vssq. Since the amplitude of the output voltage swing is about half of that of the CMOS interface in FIG. 1(b), the same driver will be able to switch in a shorter time (T4′ instead of T4) when all the other conditions are the same, as illustrated in FIG. 2(b).

Similar to the example in FIG. 1(b), the rising edge of the complementary clock signal (CK #) at time T5 triggers the output driver to send out another data. FIG. 2(b) also illustrates the procedures to switch the output voltage from SAI lower voltage (Vos) back to SAI upper voltage (Voh). To prevent the flow through current noise problem, it is still important to turn off MN by pulling Vgn toward Vssq at an earlier time (T5) before pulling Vgp toward Vssq at a latter time (T6). After T6, the n-channel pull down transistor (MN) is turned off and the p-channel pull up transistor (MP) starts to pull output voltage (Vq′) up to Voh as shown by the waveforms in FIG. 2(b) between time T7 and T8′. Again, the switching is finished in a shorter time (T8′ instead of T8) due to smaller voltage swing.

We can turn off this output driver (DR1) by setting Vgp=Vddq and Vgn=Vssq so that the output driver is in a high impedance state to allow other output drivers (DR2, DR3) to drive Q′.

SAI methods improve interface performance by reducing the amplitude of switching output signals. That is achieved by using a termination resistor to serve as a voltage divider; however, unlike the traditional CMOS output driver, the SAI circuits consume power at quiescent state. Typically, a SAI driver needs to provide a steady-state current of about 15 milli-Amps across the termination resistor. A 72-signal data bus will consume about 1 Amp of current even when there is no switching activity. This is a tremendous waste of energy, particularly for portable applications that are battery powered. In addition, SAI drivers still suffer from the same switching noise problems and the “flow through current prevention delay time” as CMOS output drivers. It is highly desirable to provide an output driver that has the advantages of small amplitude switching while removing the noise and power problems.

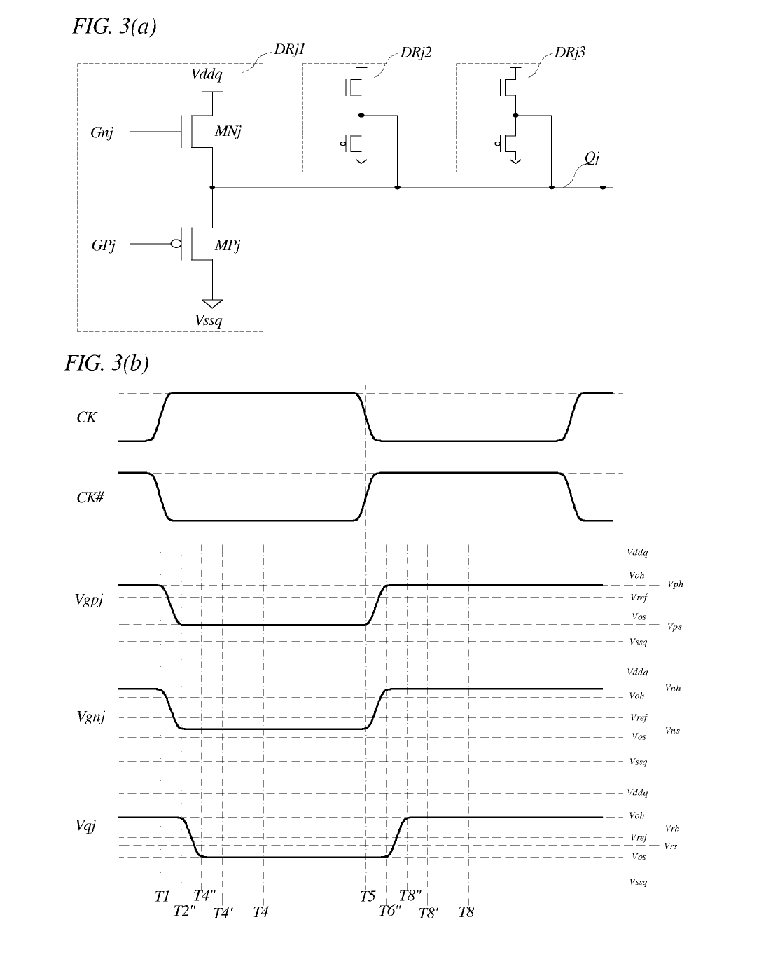

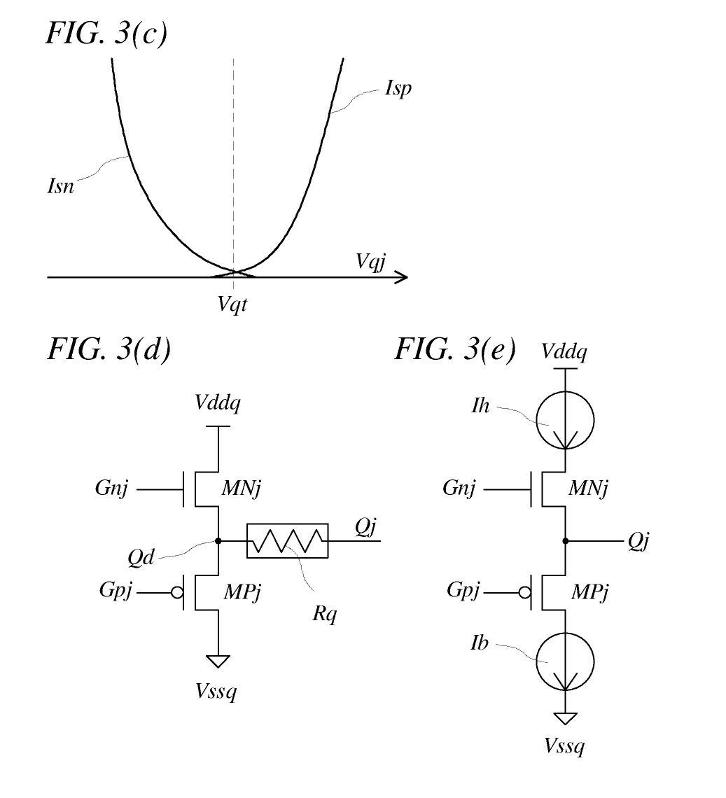

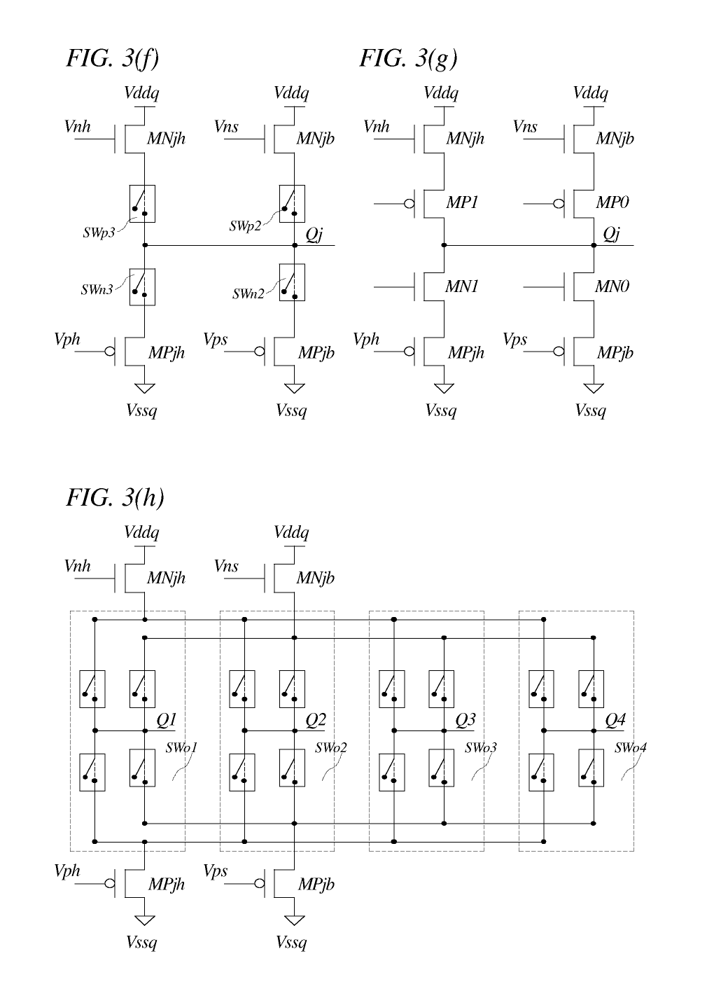

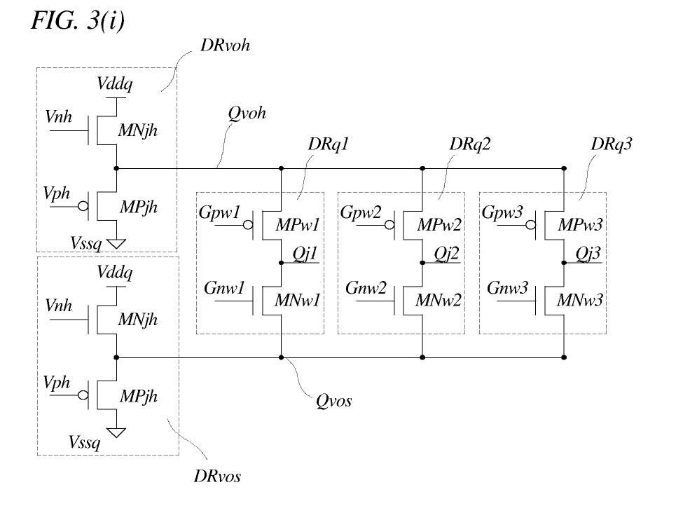

FIG. 3(a) is a schematic diagram showing simplified structures for an output driver (DRj1) of the preferred embodiments of the present invention. This output driver (DRj1) also comprises a p-channel transistor (MPj) and an n-channel transistor (MNj). However, unlike the prior art CMOS output driver, the p-channel transistor (MPj) is configured as a pull down transistor and the n-channel transistor (MNj) is configured as a pull up transistor. The preferred embodiments of the present invention thus inverts the roles of the driving transistors in traditional CMOS output drivers by using n-channel transistors as pull up transistors and by using p-channel transistors as pull down transistors to drive external signals.

In FIG. 3(a), the source electrode of the n-channel pull up transistor (MNj) is connected to an upper voltage supply line at voltage Vddq, and the source electrode of the p-channel pull down transistor (MPj) is connected to a lower voltage supply line at voltage Vssq, where Vssq<Vddq and is often set to ground voltage. The drain electrode of the p-channel pull down transistor (MPj) and the drain electrode of the n-channel pull up transistor (MNj) are both connected to an external signal line (Qj). At driving conditions, the gate electrode (Gnj) of the n-channel pull up transistor (MNj) is preferably set to a gate voltage (Vgnj) that is higher than the target output voltage (Vqtn) by about one threshold voltage (Vtn) of the n-channel transistor (MNj), which means Vgnj is preferably about (Vqtn+Vtn). The gate electrode (Gpj) of the p-channel pull down transistor (MPj) is preferably set to a gate voltage (Vgpj) that is lower than the target output voltage (Vqtp) by about one threshold voltage (Vtp) of the p-channel transistor (MPj), which means Vgpj is preferably about (Vqtp−Vtp).

In this configuration, the channel current of the pull up n-channel transistor (MNj) is controlled by its gate voltage Vgnj relative to the output voltage (Vqj). When (Vgnj−Vqj) is smaller than the threshold voltage (Vtn) of the n-channel transistor (MNj), the transistor is turned off. When (Vgnj−Vqj) is larger than Vtn, the channel current (Isn) of the n-channel pull up transistor (MNj) can be described by a textbook equation as

Isn=Kn(Wn/Ln)(Vgnj−Vqj−Vtn)²˜Kn(Wn/Ln)(Vqtn−Vqj)² (EQ 1)

where (Wn/Ln) is the width/length ratio of the transistor, and Kn is a parameter dependent on electron mobility. In other words, the n-channel pull up transistor (MNj) will pull up the output voltage Vqj toward the target voltage Vqtn if its gate voltage is set as Vgnj˜Vqtn+Vtn. The driving channel current (Isn) increases rapidly as (Vqtn−Vqj) increases, but the driving current is very small when output voltage Vqj is pulled near the target voltage Vqtn. Consequently, this circuit configuration has an automatic negative feedback mechanism.

Similarly, the current driving capability of the pull down p-channel transistor (MPj) is controlled by its gate voltage Vgpj relative to the output voltage (Vqj). When (Vqj−Vgpj) is smaller than the amplitude of the threshold voltage (Vtp) of the p-channel transistor (MPj), the transistor is turned off. When (Vqj−Vgpj) is larger than Vtp, the channel current (Isp) of the p-channel pull down transistor (MPj) can be described by a textbook equation as

Isp=Kp(Wp/Lp)(Vqj−Vgpj−Vtp)²˜Kp(Wp/Lp)(Vqj−Vqtp)² (EQ 2)

where (Wp/Lp) is the width/length ratio of the transistor, and Kp is a parameter dependent on hole mobility. In other words, the p-channel pull down transistor (MPj) will pull down the output voltage Vqj toward the target voltage Vqtp if its gate voltage is set as Vgpj˜Vqtp−Vtp. The driving channel current increases rapidly with (Vqj−Vqtp) but the driving current is very small when output voltage Vqj is pulled near the target voltage Vqtp. Again, this circuit configuration has an automatic negative feedback mechanism.

For many applications according to the preferred embodiments, the target voltage (Vqtn) for the n-channel pull up transistor and the target voltage (Vqtp) for the p-channel pull down transistor are set to be about the same, at about Vqtp˜Vqtn˜Vqt. However, there are exceptions.

FIG. 3(c) shows the current-voltage relationship of the output driver (DRj1) when Vqtp˜Vqtn˜Vqt according to Equations 1 and 2. The actual current-voltage (I-V) relationships of modern transistors are more complicated than those simplified equations (EQ 1, EQ 2). For example, the threshold voltages (Vtp, Vtn) are also complex functions of bias voltages due to body effects. Nevertheless, the general principles reflected in equations 1 and 2 and on FIG. 3(c) are correct. By setting gate voltages Vgpj˜Vqt−Vtp and Vgnj˜Vqt+Vtn, the output driver (DRj1) will pull the output voltage (Vqj) toward the target voltage (Vqt). The driving currents of the output driver increases rapidly with the difference between Vqj and Vqt, and the driver consumes little power once Vqj is pulled close to target voltage Vqt. In other words, an output driver of the preferred embodiments of the present invention can pull its output voltage to a partial voltage with strong driving power, while holding the output voltage at the target voltage without consuming much power.

Known reference voltage generators have used similar negative feedback mechanisms to generate reference voltages at fixed levels. A typical example would be the bit line pre-charge voltage generator for memory devices as discussed in U.S. Pat. No. 6,216,246. Reference voltage generators are designed to drive constant or near-constant target voltages; the output voltages of reference voltage generators may be adjustable, but reference voltage generators are not designed to support frequent switching output voltages. The present invention discloses methods to use n-channel pull up transistors in combination with p-channel pull down transistors to drive high performance synchronized switching interface signals so that the circuit structures and designs are optimized to reduce switching noise and to improve switching performance.

Based on the above principles, the output driver (DRj1) shown in FIG. 3(a) can drive output signals compatible with the SAI signals shown in FIG. 2(b) without a termination resistor (Rref). When the gate voltage of the n-channel pull up transistor is set as Vgnj=Vnh˜Voh+Vtn, and the gate voltage of the p-channel pull down transistor is set as Vgpj=Vph˜Voh−Vtp, the driver will pull the output voltage (Vqj) toward SAI upper voltage (Voh). However, unlike the SAI driver in FIG. 2(b), a driver of the preferred embodiments can hold the voltage at Voh without using a termination resistor (Rref) and without drawing significant power at quiescent state. If the output voltage (Vqj) drifts significantly below Voh, the n-channel pull up transistor (MNj) will have a strong driving power to pull Vqj back to Voh while the p-channel pull down transistor (MPj) remains off. If the output voltage (Vqj) drifts significantly above Voh, the p-channel pull down transistor (MPj) will have a strong driving power to pull Vqj back to Voh, while the n-channel pull up transistor (MNj) remains off. When the gate voltage of the n-channel pull up transistor is set as Vgnj=Vns=Vos+Vtn, and the gate voltage of the p-channel pull down transistor is set as Vgpj=Vps=Vos−Vtp, the driver (DRj1) will pull the output voltage (Vqj) toward SAI lower voltage (Vos). However, unlike the SAI driver in FIG. 2(b), the output driver of the preferred embodiments can hold the voltage at Vos without a termination resistor (Rref) and without drawing significant power at quiescent state. If the output voltage (Vqj) drifts significantly below Vos, the n-channel pull up transistor (MNj) will have a strong driving power to pull Vqj back to Vos, while the p-channel pull down transistor (MPj) remains off. If the output voltage (Vqj) drifts significantly above Vos, the p-channel pull down transistor (MPj) will have a strong driving power to pull Vqj back to Vos, while the n-channel pull up transistor (MNj) remains off.

FIG. 3(b) shows exemplary timing waveforms to illustrate the operational principles of the output driver of FIG. 3(a) in comparison to the SAI driver of FIG. 2(b). Before time T1, gate voltage Vgpj is set to Vph˜Voh−Vtp and gate voltage Vgnj is set to Vnh˜Voh+Vtn. As discussed in previous sections, the output voltage (Vqj) is held at SAI upper voltage (Voh) under this condition; the output voltage is therefore compatible with the SAI voltage shown in FIG. 2(b). The rising edge of clock signal (CK) at time T1 triggers the driver to send out the next data. At time T1, Vgpj begins transitioning to Vps, and Vgnj begins transitioning to Vns, as shown in FIG. 3(b). Importantly, MNj typically remains off during this switching event, and thus there is no flow through current. Consequently, and unlike the SAI driver in FIG. 2(b), both gate voltages can be switched simultaneously without adding a “flow through current prevention delay time.” The switching time of gate voltages (Vgnj, Vgpj) also can be shorter than other drivers because of the smaller switching amplitudes. Therefore, both gate voltages should be stable at a time (T2″), which is faster than the time (T3) for the other output drivers shown in previous examples. The p-channel pull down transistor (MPj) has strong driving power to pull Vqj toward Vos, and the driving power will decrease as Vqj is driven closer to target voltage Vos. In other words, an output driver of the preferred embodiments consumes significant power only when the output voltage differs from the target voltage. This efficient usage of power helps to minimize switching noise. In addition, the gate voltages (Vgpj, Vgnj) switch in the same direction as the output voltage. Therefore, the capacitor coupling effect actually improves rather than decreases the signal switching speed. Due to the above advantages, the output driver of the preferred embodiments can switch the output voltage (Vqj) to Vos at a time (T4″) as illustrated in FIG. 3(b), which is faster than the time required by the SAI driver (T4′), as shown in FIG. 2(b). The driver (DRj1) will hold Vqj at Vos, making it fully compatible with the SAI interface with or without using a termination resistor.

Similar to the example in FIG. 1(b), the rising edge of the complementary clock signal (CK #) at time T5 triggers the driver to send out the next bit of data. FIG. 3(b) also illustrates the procedures to switch the output voltage from SAI lower voltage (Vos) back to SAI upper voltage (Voh). At time T5, the process of transitioning the output voltage (Vqj) to Voh begins as Vgpj is pulled towards Vph, and Vgnj is pulled towards Vnh as shown in FIG. 3(b). Since MPj will remain off during this switching event, both gate voltages can be switched simultaneously without adding “flow through current prevention delay time”. Again, the switching time of gate voltages (Vgnj, Vgpj) can be faster than other output drivers, in part because of smaller switching amplitudes. Therefore, both gate voltages should be stable at a time (T6″), which is faster than the time required by the SAI driver (T7), as shown in FIG. 2(b). The n-channel pull up transistor (MNj) has strong driving power to pull Vqj toward Voh, and the driving power will decrease as Vqj is driven closer to target voltage Voh. This automatic adjustment in driving capability can reduce switching noise dramatically. In addition, the capacitor coupling voltages has the same polarity as the output voltage. In other words, the capacitor coupling effect actually helps the switching process. Due to the above advantages, the output voltage (Vqj) of the preferred embodiments can be switched to Voh at a time (T8″) as illustrated in FIG. 3(b), which is faster than SAI driver (at time T8′) as illustrated in FIG. 2(b). The driver (DRj1) will hold Vqj at Voh, making it fully compatible with SAI without using the termination resistor (Rref).

The above example shows that output drivers of the preferred embodiments can drive output signals at voltage levels fully compatible with existing SAI systems while achieving better performance and consuming less power.

The output driver (DRj1) of the preferred embodiments can be turned off by setting Vgpj=Vddq and Vgnj=Vssq so that the output driver is in a high impedance state to allow other output drivers (DRj2, DRj3) to drive Qj. Another method for placing the output driver (DRj1) into a high impedance state is to set Vgpj=Vph and Vgnj=Vns. Under these conditions, the output driver allows other drivers to drive Qj while at the same time tending to confine the output voltage (Vqj) to within SAI ranges (between Voh and Vos) even when no driver is activated. This is an example of the situation when the target voltage for the n-channel pull up transistor is different than the target voltage for the p-channel pull down transistor.

The above example shows that the output driver of the present invention has the following advantages over prior art SAI drivers:

(1) It can drive output voltages that are fully compatible with SAI standards (such as the HSTL, SSTL, GTL, or BTL interface standards) without using a termination resistor, thereby achieving significant power savings.

(2) The gate voltages of the output driver of the preferred embodiments also swing within relatively small amplitudes, making it possible to achieve faster switching times.

(3) The gate voltages switch in the same direction as the output voltage so that capacitor coupling noise problems are reduced.

(4) The pull up transistor and the pull down transistor of an output driver of the preferred embodiments are typically not turned on simultaneously at normal operations. Therefore, a “flow through current prevention delay time” is not required and accordingly the switching time is faster, and the control circuit is simpler.

(5) The output driver of the preferred embodiments has strong driving power when the output voltage is far from the target voltage, while the driving power decreases as the output voltage approaches the target voltage. This automatic adjustment in driving power minimizes the switching noise while at the same time achieving short switching times and high switching frequency.

(6) The output driver of the preferred embodiments can be biased into a high impedance state while at the same time stabilizing the output voltage within the SAI range without using a termination resistor.

Although some of the output drivers of the preferred embodiments generate smaller drive currents than some alternative output drivers of equivalent size (due to smaller gate to source bias voltages and body effects), the drive currents of the preferred embodiments can be improved by using larger or faster transistors, or alternatively by reducing the threshold voltages of the transistors.

While the preferred embodiments have been illustrated and described herein, other straightforward modifications and changes will be evident to those skilled in the art. The basic structure for an output driver of the present invention comprises an n-channel pull up transistor and/or a p-channel pull down transistor. A circuit designer can use many kinds of equivalent circuits to build the same output driver. We will discuss a few examples in the following sections. It is to be understood that there are many other possible modifications and implementations so that the scope of the invention is not limited by the specific embodiments discussed herein.

FIG. 3(d) shows a modification to the previously described output driver in which a series termination resistor (Rq) or other current limiting device is placed between the internal signal line (Qd) of an output driver and an external signal line (Qj). Utilized in this manner, such a series termination resistor (Rq) or other type of current limiting device can reduce signal reflections on the external signal line (Qj). The series termination resistor (Rq) or other current limiting device can be integrated into the IC chip or implemented as a discrete circuit component. For example, DDR (double data rate) DRAMs utilize discrete series termination resistors while DDR2 and DDR3 DRAMs provide the option to implement the series termination resistors as part of the monolithic DRAM IC chip.

FIG. 3(e) shows another type of current limiting method for output drivers of the preferred embodiments. The source electrode of the n-channel pull up transistor (MNj) is connected to a current source (Ih) that is connected to a power line at voltage Vddq. The source electrode of the p-channel pull down transistor (MPj) is also connected to another current source (Ib) that is connected to power line at voltage Vssq, where Vssq<Vddq. This modification is designed to avoid current overshoot. This method is effective in reducing switching noise, especially for inductance induced noise. Replacing the current sources (Ih, Ib) with resistors or other types of current limiting devices can provide a similar effect.

FIG. 3(e) represents current sources as symbols instead of as actual transistor level schematics. A “current source” here includes any circuit element that provides for current control including, but not limited to, (1) a transistor that is biased into saturation conditions, (2) a current limiting device such as a simple resistor, and (3) a much more complicated circuit. The current sources referred to in the preferred embodiments also do not need to be ideal current sources. For example, as used herein, current sources include current limiting devices. The most common circuits used as current sources are “current mirrors,” which are well known to circuit designers. Methods to design current sources are well known to most circuit designers and will not be described in further detail here. For simplicity, current limiting devices are represented generically herein by an arrow in a circle as Ih or Ib in FIG. 3(d) and referred to as “current sources”. The scope of this invention should not be limited by the nature of the detailed implementation of those current sources.

For the examples described in FIG. 3(b), the output voltage (Vqj) is changed by switching the gate voltages (Vgpj, Vgnj). FIG. 3(f) illustrates a modification of the output driver that can achieve the same purpose without requiring switching the gate voltages. The gate electrode of an n-channel pull up transistor (MNjh) is driven at a fixed voltage Vnh˜Voh+Vtn. The source electrode of MNjh is connected to an I/O voltage supply line at voltage Vddq, and the drain electrode of MNjh is connected to a switch (SWp3) that is connected to the external signal line (Qj). The gate electrode of another n-channel pull up transistor (MNjb) is driven at a fixed voltage Vns˜Vos+Vtn. The source electrode of MNjb is connected to an I/O voltage supply line at voltage Vddq, and the drain electrode of MNjb is connected to a switch (SWp2) that is connected to the external signal line (Qj). The gate electrode of a p-channel pull down transistor (MPjh) is driven at a fixed voltage Vph˜Voh−Vtp. The source electrode of MPjh is connected to a lower voltage supply line at voltage Vssq (Vssq<Vddq), and the drain electrode of MPjh is connected to a switch (SWn3) that is connected to the external signal line (Qj). The gate electrode of another p-channel pull down transistor (MPjb) is driven at a fixed voltage Vps˜Vos−Vtp. The source electrode of MPjb is connected to lower voltage supply line at voltage Vssq, and the drain electrode of MPjb is connected to a switch (SWn2) that is connected to the external signal line (Qj). FIG. 3(g) illustrates one example of the transistor level schematic diagram for the circuit in FIG. 3(f). The quiescent state output voltages of the driver in FIG. 3(f) are determined by the states of the switches (SWp3, SWp2, SWn3, SWn2) according to table 1. Through proper control of those switches, the driver in FIG. 3(f) can support the SAI functions shown in FIG. 3(b).

TABLE 1

| SWp3 | SWp2 | SWn3 | SWn2 | |
|---|---|---|---|---|
| state | state | state | state | Driver output state |
| on | Off | on | Off | Pull to Voh |
| off | On | off | On | Pull to Vos |
| off | On | on | Off | Driver off while holding |
| | | | | Vqj between Voh and Vos |
| off | Off | off | Off | Driver completely off |

A major advantage of the output driver in FIG. 3(f) is that it can have almost no capacitive coupling noise. During each switching event, the gate voltages are not changed while the control voltages on switches swing in opposite directions to cancel the coupling effects from each other. In this configuration, there is almost no limit on the size of driving transistors (MNjh, MNjb, MPjh, MPjb) because they are biased at constant voltages so that they will not cause substantial noise problems. One set of driving transistors (MNjh, MNjb, MPjh, MPjb) can be shared by many switches that are connected to many output signals. FIG. 3(h) shows an example in which one set of driving transistors (MNjh, MNjb, MPjh, MPjb) are shared by four 4-switch-sets (SWo1, SWo2, SWo3, SWo4) controlling 4 external signal lines (Q1, Q2, Q3, Q4). Each 4-switch-set (SWo1, SWo2, SWo3, SWo4) in FIG. 3(h) supports the same functions as the 4 switches (SWp3, SWp2, SWn3, SWn2) in FIG. 3(f) and each can control its output (Q1, Q2, Q3, Q4) in the same manner reflected in Table 1.

It is also possible to combine multiple methods such as those illustrated in FIGS. 3(d-g) to minimize noise problems.

FIG. 3(i) shows yet another design variation. This circuit uses a driver (DRvoh) of the preferred embodiments configured to drive an internal line (Qvoh) at upper SAI voltage (Voh). This line (Qvoh) is connected to the source electrode(s) of one or a plurality of p-channel pull up transistors (MPw1, MPw2, MPw3). It also uses another driver (DRvos) of the preferred embodiments configured to drive an internal line (Qvos) at lower SAI voltage (Vos). This line (Qvos) is connected to the source electrode(s) of one or a plurality of n-channel pull down transistors (MNw1, MNw2, MNw3). The drain electrode(s) of p-channel pull up transistors (MPw1, MPw2, MPw3) and the drain electrode(s) of n-channel pull down transistors (MNw1, MNw2, MNw3) are connected to one or a plurality of external signal lines (Qj1, Qj2, Qj3) as shown in FIG. 3(i). The drivers configured this way are able to drive SAI signals without using termination resistors. However, such drivers still suffer from the same switching and coupling noises previously described.

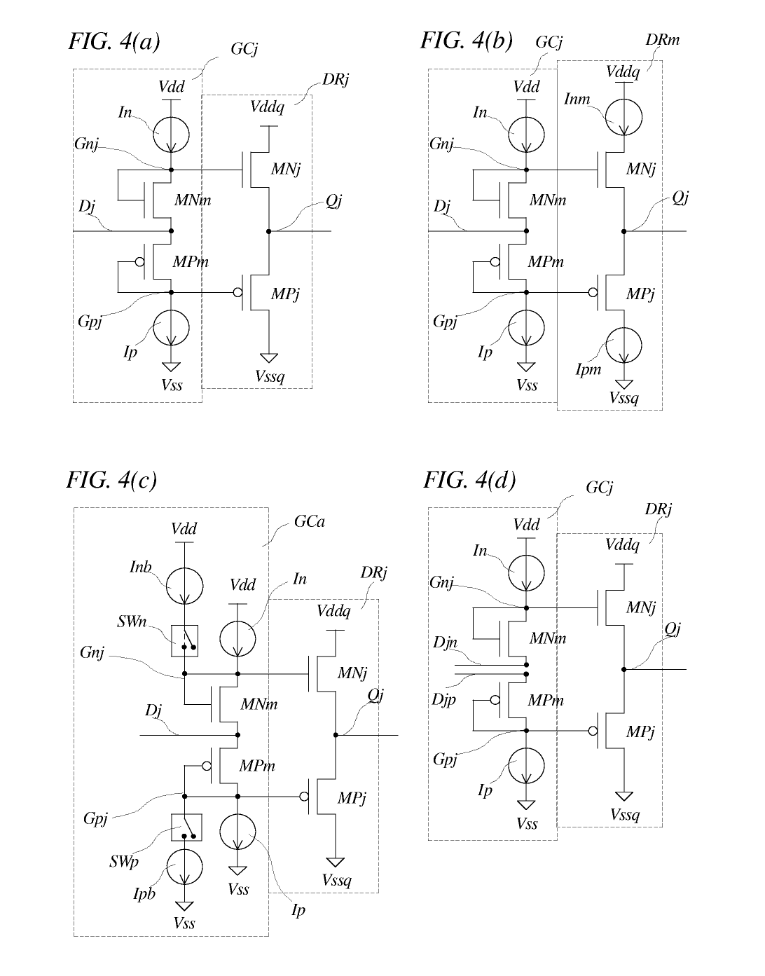

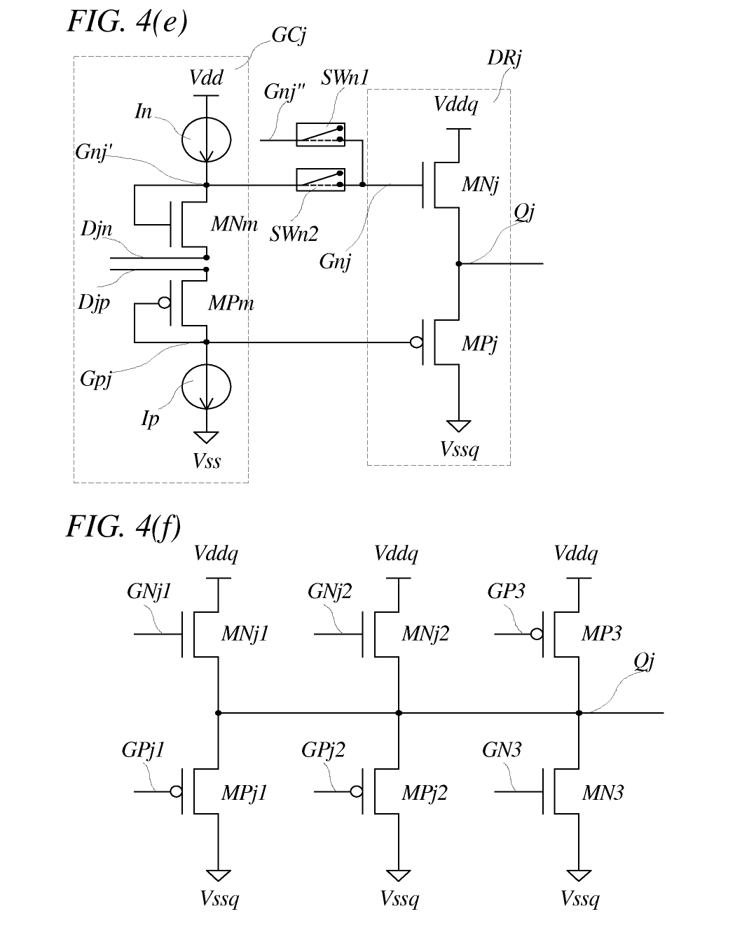

The output driver of the preferred embodiments of the present invention utilizes gate voltages about one threshold voltage away from target output voltages. The transistor threshold voltages (Vtn, Vtp) can be a complex function of, e.g., manufacturing procedures, substrate voltages, temperature, and device geometry. It is therefore good practice to provide adequate support circuitry to generate appropriate gate voltages for the output drivers of the preferred embodiments of the present invention. FIG. 4(a) is a schematic diagram illustrating one example of gate voltage generation circuits (GCj). The output driver (DRj) in FIG. 4(a) has the same structure as the output driver (DRj1) in FIG. 3(a). The gate electrode of the n-channel pull up transistor (MNj) is connected to the gate electrode and the source electrode of an n-channel matching transistor (MNm), and to one terminal of a current source (In). The other terminal of the current source (In) is connected to a voltage supply line at voltage Vdd. Vdd can be the same as Vddq; it also can be different. The drain electrode of the n-channel matching transistor (MNm) is connected to an input line (Dj) as shown in FIG. 4(a). In one preferred embodiment, the electrical properties of the matching transistor (MNm) are similar to the n-channel pull up transistor (MNj). For this circuit configuration, the gate voltage (Vgnj) of the n-channel pull up transistor (MNj) is related according to theory to the current (Iin) of the current source (In) and the input voltage (Vdj) of the input line (Dj) as

Iin=Kn(Wnm/Lnm)(Vgnj−Vdj−Vtn)² (EQ 3)

where (Wnm/Lnm) is the width/length ratio of the n-channel matching transistor (MNm), and Kn is a parameter related to electron mobility. If there is a good match between MNm and MNj, the parameter Kn in EQ 1 and in EQ 3 should be the same, and their threshold voltages should therefore be the same. When the current (Iin) of the current source (In) is small, (Vgnj−Vdj)˜Vtn and the gate bias voltage is approximately one threshold voltage above the target voltage (Vdj). Using EQ 1 and EQ 3, when Vqj>Vdj, the driver current (Isn) of the n-channel pull up transistor can be approximated as

Isn˜Iin[(Wn/Ln)/(Wnm/Lnm)](Vqj−Vdj)² (EQ 4),

meaning that the n-channel pull up transistor (MNj) will try to pull Vqj toward Vdj, and that the channel current of the n-channel pull up transistor is proportional to the current (Iin) of the current source (In) in the gate voltage generation circuit (GCj).

Similarly, the gate electrode of the p-channel pull down transistor (MPj) is connected to the gate electrode and the source electrode of a matching p-channel transistor (MPm), and to one terminal of a current source (Ip). The other terminal of the current source (Ip) is connected to a lower voltage supply line at voltage Vss, where Vss<Vdd. Vss can be the same as Vssq; it also can be different. The drain electrode of the matching transistor (MPm) is connected to the input line (Dj) as shown in FIG. 4(a). In one preferred embodiment, the electrical properties of the matching transistor (MPm) are similar to the p-channel pull down transistor (MPj). For the circuit configuration in FIG. 4(a), the gate voltage (Vgpj) of the p-channel pull down transistor (MPj) is related according to theory to the current (Iip) of the current source (Ip) and the input voltage (Vdj) on the input line (Dj) as

Iip=Kp(Wpm/Lpm)(Vdj−Vgpj−Vtp)² (EQ 5)

where (Wpm/Lpm) is the width/length ratio of the p-channel matching transistor (MPm), and Kp is a parameter related to hole mobility. If there is a good match between MPm and MPj, the parameter Kp in EQ 2 and EQ 5 should be identical, and they should have approximately the same threshold voltage. When the current (Iip) of the current source (Ip) is small, (Vdj−Vgpj)˜Vtp and the gate bias voltage is approximately one threshold voltage below the target voltage (Vdj). Using EQ 2 and EQ 5, when Vdj>Vqj, the driver current (Isp) of the p-channel pull down transistor can be approximated as

Isp˜Iip[(Wp/Lp)/(Wpm/Lpm)](Vdj−Vqj)² (EQ 6),

meaning that the p-channel pull down transistor will try to pull Vqj toward Vdj, and the channel current of the p-channel pull down resistor (MPj) is proportional to the current (Iip) of the current source (Ip) in the gate voltage generation circuit (GCj).

If the two current sources (In, Ip) provide the same currents (Iin=Iip), and if [(Wn/Ln)/(Wnm/Lnm)]=[(Wp/Lp)/(Wpm/Lpm)], then at quiescent state Vqj˜Vdj. In other words, the output voltage (Vqj) will automatically follow the input voltage (Vdj) when the gate voltage generator (GCj) in FIG. 4(a) is used to provide gate voltages for the driver (DRj). Under these circumstances, the quiescent state leakage current of the output driver is roughly equal to Iin[(Wn/Ln)/(Wnm/Lnm)]. If the current sources (In, Ip) perform as ideal current sources, the output driver circuit in FIG. 4(a) will serve as an excellent analog driver; the output voltage (Vqj) on external signal line (Qj) can follow the input voltage (Vdj) on the input signal line (Dj) with great accuracy.

FIG. 4(b) shows another circuit example of the preferred embodiments of the present invention that has the same gate voltage generation circuits (CGj) as those in FIG. 4(a) and has matching current sources (Inm, Ipm) at its output driver (DRm). The source of the n-channel pull up transistor (MNj) in this output driver (DRm) is connected to one terminal of a matching current source (Inm) having electrical characteristics similar to the current source (In) in the gate voltage generation circuit (GCj). The source of the p-channel pull down transistor (MPj) in the output driver (DRm) is connected to one terminal of a matching current source (Ipm) having electrical characteristics similar to the current source (Ip) in GCj. This circuit in FIG. 4(b) is designed to eliminate non-ideal effects caused by mismatches in source-to-drain bias voltages so as to achieve excellent accuracy. It offers excellent control over both output voltages and output currents, making it ideal for high accuracy applications.

As shown by EQ 3-EQ 6, the driving power as well as the quiescent state leakage current of the driver in FIG. 4(a) are proportional to the currents generated by current sources (In, Ip) in the gate voltage generation circuit (GCj). For applications that require low power, the currents can be minimized to achieve extremely low power consumption while at the same time maintaining high accuracy. For applications that require high speed, the currents can be increased to achieve excellent switching speed while at the same maintaining high accuracy. For applications that require both high switching speed and low power consumption, variable current sources can be used as shown by the example in FIG. 4(c). The output driver (DRj) in FIG. 4(c) has the same structure as the output driver in FIG. 4(a). The gate voltage generation circuit (GCa) in FIG. 4(c) has a structure similar to the gate voltage generation circuit (GCj) in FIG. 4(a), except that (1) the gate electrode (Gnj) of the n-channel pull up transistor (MNj) is connected to an additional switch (SWn) that is connected to an additional current source (Inb), and (2) the gate electrode (Gpj) of the p-channel pull down transistor (MPj) is connected to an additional switch (SWp) that is connected to an additional current source (Ipb), as shown in FIG. 4(c). In this example, the current source Inb is designed to provide (when switch SWn is closed) a much larger current than the current source In, and the current source 103 is designed to provide (when switch SWp is closed) a much larger current than the current source Ip. When conditions require that the output voltage be switched at high speed, both switches (SWn, SWp) can be closed to increase the driving power of the driver (DRj). However, when high switching speed is not required (e.g., when the output voltage has already been switched and a quiescent state is desired), the switches (SWn, SWp) can be opened so that the circuitry consumes very low power to hold the output voltage at the new voltage level. It is also possible to close SWn while SWp remains open to increase pull up speed without influencing pull down speed. Similarly, it is also possible to close SWp while SWn remains open to increase pull down speed without influencing pull up speed. It is therefore possible to adjust the driving power of the output driver according to its needs at proper time periods. This example demonstrates the flexibility of the preferred embodiments of the present invention in supporting both high speed and low power applications while simultaneously using the output drivers described herein.

While specific embodiments of the invention have been illustrated and described herein, other modifications and changes will occur to those skilled in the art. For example, the current sources in the above examples can be replaced with other current limiting circuits such as resistors and the circuits will still work. The currents of the current sources certainly can be changed using analog methods instead of using switches. It is therefore to be understood that there are many other possible modifications and implementations so that the scope of the invention is not limited by the specific embodiments discussed in this patent disclosure.

FIG. 4(d) shows one example of design variation for a circuit that is nearly identical to the circuit in FIG. 4(a) except that it has two input lines (Djn, Djp); one input line (Djn) is connected to the drain electrode of the n-channel matching transistor (MNm) while the other input line (Djp) is connected to the drain electrode of the p-channel matching transistor (MPm). The use of two input lines (Djn, Djp) allows a target voltage to be assigned for the n-channel pull up transistor (MNj) that is different than the target voltage for the p-channel pull down transistor (MPj). For example, if the voltage (Vdjn) on Djn is set lower than the voltage (Vdjp) on Djp, the quiescent state leakage current through MNj and MPj can be reduced while setting the quiescent state output voltage somewhere between Vdjn and Vdjp. If the voltage (Vdjn) on Djn is set higher than the voltage (Vdjp) on Djp, output voltage switching speed can be increased while setting the quiescent state output voltage somewhere between Vdjn and Vdjp.

FIG. 4(e) shows another example of a circuit that is nearly identical to the circuit in FIG. 4(d) except that the gate electrode (Gnj) of the n-channel pull up transistor (MNj) is connected to two switches (SWn1, SWn2) allowing it to connect either to the gate electrode (Gnj′) of the n-channel matching transistor (MNm), or to a different line (Gnj″) that is biased at a different gate voltage (Vgnj″). This circuit configuration provides a fast method to switch between different gate voltage generation circuits. One interesting option is to connect Gnj″ to an upper voltage supply line at voltage Vddq so that turning on SWn1 will provide strong driving power for quick output voltage pull up switching during transitions while also allowing for a connection to Gnj′ when the output voltage is close to target voltage. It should be obvious that similar configuration changes as those shown in FIG. 4(e) can be applied to select gate voltages for the p-channel pull down transistor (MPj), or to apply the change for both output driver transistors. More switches can be used to provide even more options.

Multiple activated output drivers of the present invention can drive the same external load; it is even possible to have other types of output drivers driving the same external load in parallel. FIG. 4(f) shows an example when two n-channel pull up transistors (MNj1, MNj2), one p-channel pull up transistor (MP3), two p-channel pull down transistors (MPj1, MPj2), and one n-channel pull down transistor (MN3) all drive the same output line (Qj) in parallel.

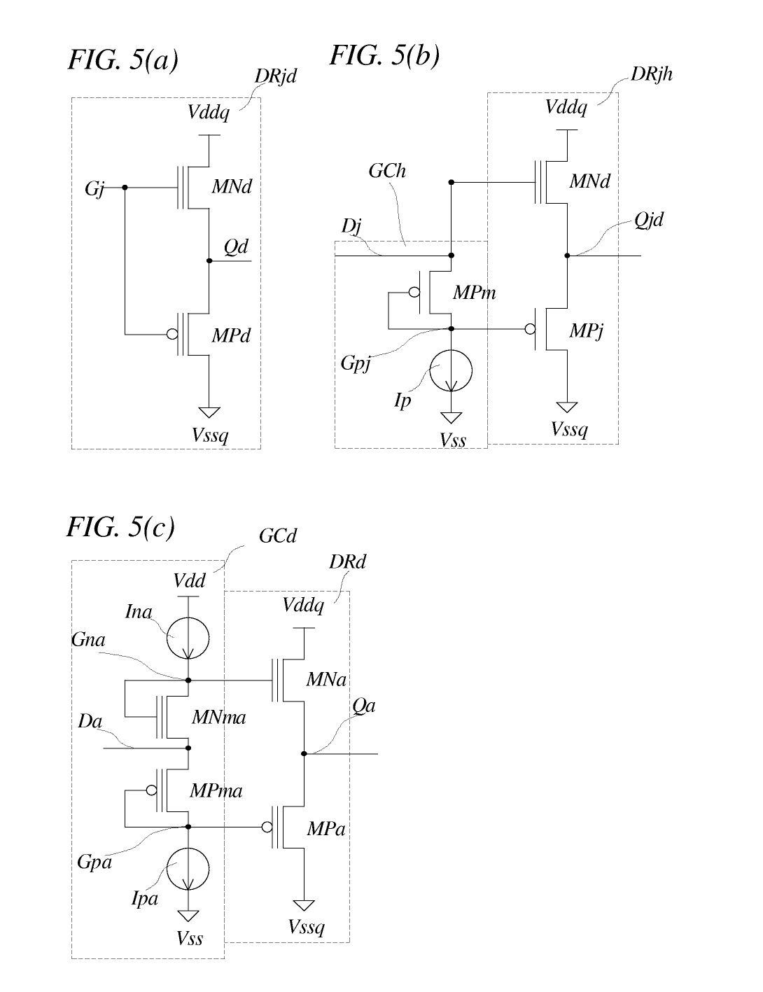

The examples in FIGS. 4(a-d) show various methods to provide gate voltages approximately one threshold voltage away from the target output voltage at operation conditions. One option is to use transistors with threshold voltages close to zero. A transistor with a threshold voltage close to zero is referred to herein as a “native transistor.” FIG. 5(a) shows an output driver (DRjd) comprising a native n-channel pull up transistor (MNd) with threshold voltage Vtn˜0, and a native p-channel pull down transistor (MPd) with threshold voltage Vtp˜0. Because there is no standardized symbol that represents native transistors, the symbols for floating gate transistors are used herein to represent native transistors in the figures and schematic diagrams. Using native transistors, an input line (Gj) can be connected to the gate electrode of the native n-channel pull up transistor (MNd) as well as to the gate electrode of the native p-channel pull down transistor (MPd), and the output voltage will follow the input voltage without using any gate voltage generation circuits. The circuit in 5(a) has enough accuracy to support digital switching interfaces such as HSTL, SSTL, GTL, or BTL interfaces.

Prior art output drivers typically use enhancement mode transistors with high threshold voltages to reduce leakage currents. The output drivers of the preferred embodiments of the present invention have a natural feedback mechanism to reduce leakage current. To achieve better driving power for the same size transistors, it is often desirable to use transistors with lower threshold voltages, native transistors, or even depletion mode transistors for output drivers of the preferred embodiments of the present invention. Many current IC manufacturing technologies make available native transistors. Alternatively, additional threshold adjustment masking steps can be added to current manufacturing technologies to manufacture transistors with desired threshold voltages for applications of the preferred embodiments present invention. As such techniques are well known, they are not further described herein. Another alternative is to use floating gate transistors in the output driver because the threshold voltages of such floating gate transistors are programmable.

Many current IC manufacturing technologies provide options for n-channel native transistors but few of them provide p-channel native transistors. FIG. 5(b) shows an output driver (Drjh) that has a native n-channel pull up transistor (MNd) and an enhancement mode p-channel pull down transistor (MPj). The supporting gate voltage generation circuit (GCh) directly connects an input line (Dj) to the gate electrode of MNd, while using a matching transistor (MPm) and a current source (Ip) to generate the gate voltage for the p-channel pull down transistor (MPj).

Due to body effects, the effective threshold voltage of a native transistor may vary from 0 volts at different operations conditions. FIG. 5(c) shows an example in which a gate voltage generation circuit (GCd) is used to adjust gate voltages even when a native n-channel pull up transistor (MNa) and a native p-channel pull down transistor (MPa) have been used in its output driver (DRd). The matching transistors (MNma, MPma) in the supporting gate voltage generation circuits (GCd) can also be native transistors. This circuit in FIG. 5(c) has better accuracy than the circuit in FIG. 5(a).

Prior art SAI drivers can only switch between two voltage levels (Voh and Vos) to represent one binary data per phase. The output drivers of the preferred embodiments of the present invention have the accuracy to switch between multiple levels of analog voltages. They can easily support four-level data format to represent two binary bits per phase, or 16-level data format to represent 4 binary bits per phase. In other words, the output drivers of the preferred embodiments of the present invention can improve data bandwidth while running at the same clock rate. When designed carefully, an output driver of the preferred embodiments of the present invention can support the functions of a high speed digital to analog (D/A) converter, providing output voltages switching between hundreds or even thousands of analog levels. Prior art high performance D/A converters consume significant power. A D/A converter equipped with an analog switching output driver of the preferred embodiments of the present invention will consume very little power, but can operate at a high switching rate while at the same time providing accurate outputs.

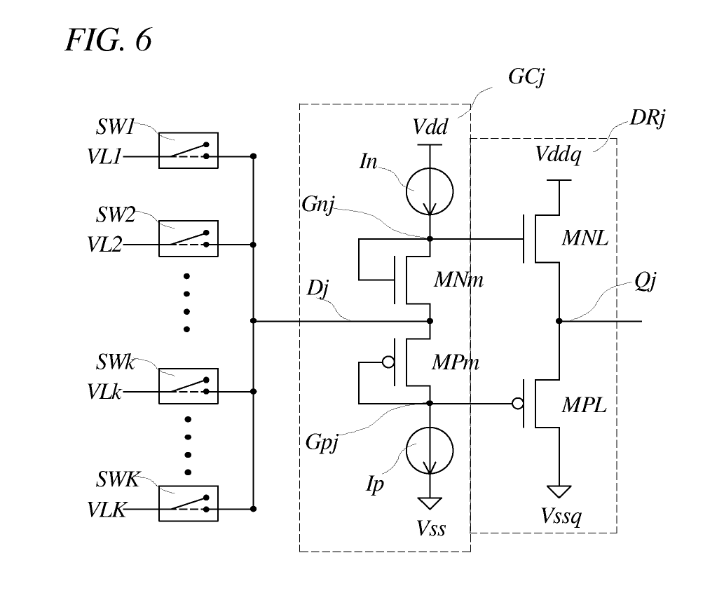

FIG. 6 is a schematic diagram for an embodiment of the output driver in FIG. 4(a) that supports multiple level switching operations using switch controlled inputs. The voltage on the input line (Dj) is controlled by a plurality of switches (SW1, SW2, . . . , SWk, . . . SWK) connected to a plurality of voltage sources at voltages (VL1, VL2, . . . , VLk, . . . VLK), where k and K are integers. The number of voltage inputs can be from 1 to thousands of levels. The target output voltage of the output driver is determined by the state of the switches. The driving power and leakage current of the output driver is determined, in part, by the currents provided by the current sources (In, Ip).

Output drivers of the preferred embodiments of the present invention can easily support 4-level switching at 500 MHz clock rate to replace HSTL or SSTL interfaces. With careful design, 8-level or 16-level high speed switching is also possible.

Liquid crystal display (LCD) output drivers come with many configurations. For example, an LCD output driver can send out 132 RGB signals (total 396 digital-to-analogy converter output signals) with 6 bit accuracy (64 levels) switching at a relatively low clock rate around 12 kHz. For battery powered portable devices, power consumption is a major concern. Most prior art digital-to-analog converters use operational amplifiers with negative feedback to provide high accuracy output signals, but operational amplifiers typically consume a lot of power and have poor switching speed. Tsuchi disclosed an LCD driver design in U.S. Pat. No. 6,124,997 that does not use operational amplifiers; the method requires pre-charging each output line before driving the next piece of data. The pre-charge operation will consume power whether the data is changed or not. Since Tsuchi only uses pull down drivers, the method is sensitive to noises that cause the output signal to drop below targeted voltages. Output drivers of the preferred embodiments of the present invention have much better accuracy; they can hold the data at targeted value with little power; and they consume little or no power when the data is not changed. LCD drivers using output drivers of the preferred embodiments of the present invention are therefore better than prior art products.

High resolution graphic displays output 1024×900 pixels of RGB (red-green-blue) data with 8 bit resolution (256 levels) on each data. That requires outputting ˜60 M 256-level data per second. Output drivers of the preferred embodiments of the present invention can support both the accuracy and the data rate.

The most popular high performance interfaces for current art memory devices are “small amplitude interfaces” (SAI), including the HSTL interface commonly used by SRAM devices and the SSTL interface commonly used by DRAM devices. As discussed previously, the output drivers of the preferred embodiments of the present invention can be designed to be fully compatible with existing SAI with or without using termination resistors, thereby achieving lower power consumption at higher speed. For many memory devices, cost efficiency is considered more important than power saving. The sizes of the output drivers discussed previously are about the same as prior art output drivers. It is therefore desirable to provide cost saving methods for SAI memory devices.

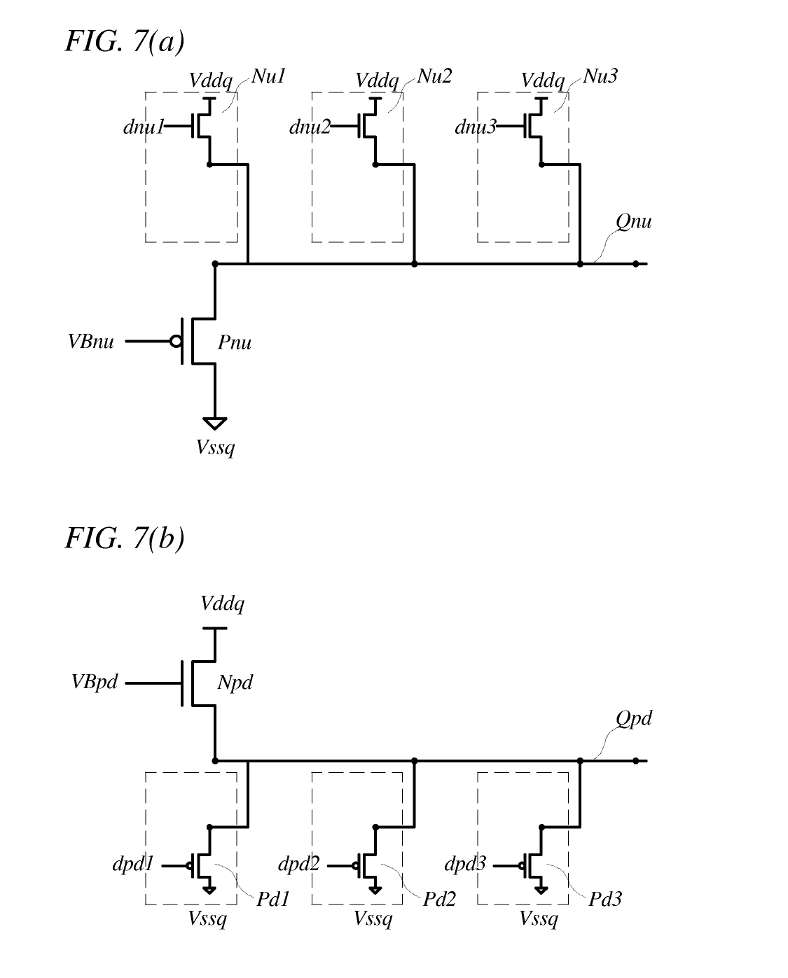

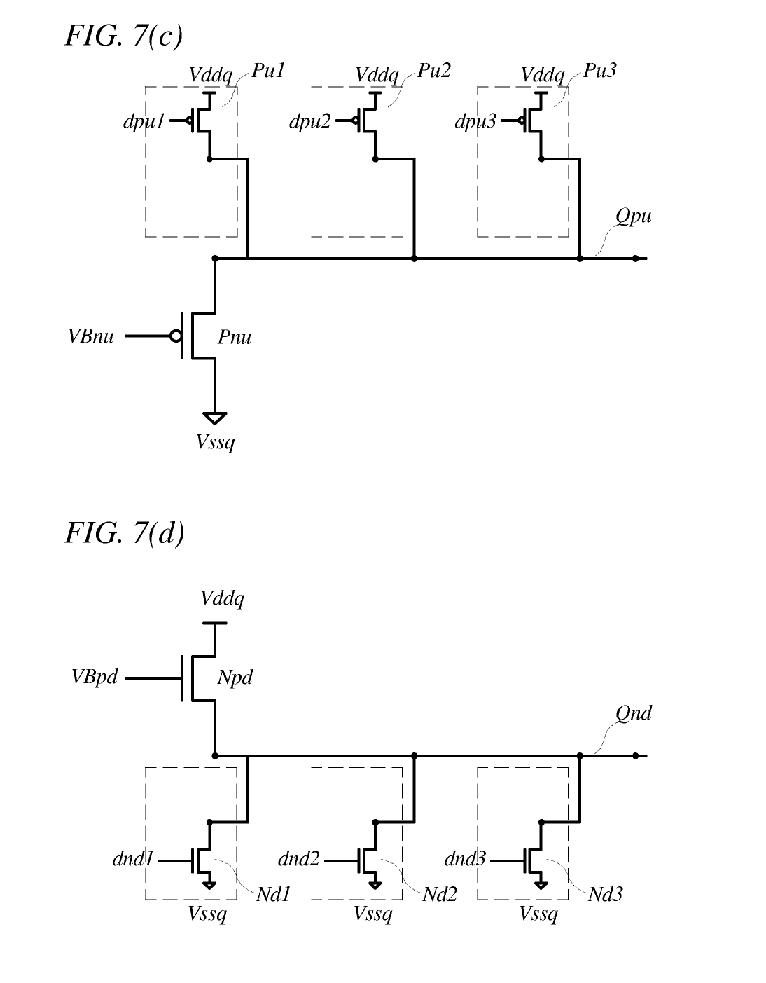

FIGS. 7(a-d) illustrate cost saving structures/methods of the preferred embodiments of the present invention using single-transistor output drivers driving against complementary termination transistors. The applications for these single-transistor output drivers of the preferred embodiments of the present invention encompass partial-voltage memory interface (PVMI) circuits. PVMI circuits use partial-voltages that are between the pull up voltage supply source (Vddq) and the pull down voltage supply source (Vssq) of the output drivers to represent data values on IC external signals in order to support memory input/output operations. Typical examples of PVMI are the HSTL interface for SRAM and the SSTL interface for DRAM. A single-transistor output driver uses one transistor to provide the majority of the switching current that drives the value of an IC external PVMI signal according to the value of its switching gate voltage. A single-transistor output driver can have many supporting circuits such as bias circuits, timing circuits, control circuits, electro-static protection circuits, and so on, but the majority of the output driving power is provided by one transistor. Such “single-transistor” certainly can comprise many legs of transistors connected in parallel to function as “one” transistor in order to provide the driving current. A complementary termination transistor (CTT) provides the driving power against single-transistor output driver(s). When the single-transistor output drivers are pull up transistors, the CTT would be a p-channel pull down termination transistor. When the single-transistor drivers are pull down transistors, the CTT would be an n-channel pull up termination transistor. An n-channel pull up termination transistor is defined as an n-channel pull up transistor that is configured to hold the steady-state voltage of an IC external PVMI signal near a pre-defined partial-voltage. Unlike the n-channel pull up transistors used in an output driver, the gate voltage of an n-channel pull up termination transistor typically is not switched when the output signal is switched. The gate voltage of termination transistor is typically held at an approximately constant level during signal switching events; said constant level may have variations due to the influence of noise. A p-channel pull down termination transistor is defined as a p-channel pull down transistor that is configured to hold the steady-state voltage of an IC external PVMI signal near a pre-defined partial-voltage. Unlike the p-channel pull down transistors used in an output driver, the gate voltage of a p-channel pull down termination transistor typically is not switched when the output signal is switched. The gate voltage of termination transistors is typically held at an approximately constant level during signal switching events; said constant level may have variations due to the influence of noise.

FIG. 7(a) is a schematic diagram showing simplified structures for output drivers of the preferred embodiments of the present invention that are designed to achieve low cost at high performance. To achieve optimum cost efficiency, each output driver is simplified to be a single-transistor driver (i.e., ignoring the termination transistor). For the example in FIG. 7(a), an IC external PVMI signal (Qnu) is driven by one single-transistor driver in each IC chip. For example, a single-transistor driver (Nu1) can be an output driver in a DRAM, another single-transistor driver (Nu2) can be an output driver in an SRAM, while another single-transistor driver (Nu3) can be an output driver in a chipset. For the example in FIG. 7(a), these single-transistor drivers (Nu1, Nu2, Nu3) are configured as n-channel pull up transistors controlled by switching gate voltages (dnu1, dnu2, dnu3). The sources of these n-channel pull up transistors (Nu1, Nu2, Nu3) are connected to pull up voltage supply source (Vddq). The drains of these n-channel pull up transistors (Nu1, Nu2, Nu3) are connected to the PVMI signal line (Qnu). The data value of the PVMI signal (Qnu) is determined by switching gate signals (dnu1, dnu2, dnu3) of the n-channel pull up transistors (Nu1, Nu2, Nu3). These n-channel pull up transistors (Nu1, Nu2, Nu3) only can pull up the voltage on the IC external PVMI signal (Qnu). A p-channel pull down termination transistor (Pnu) is therefore included to provide the pull down driving power. The source of the p-channel pull down termination transistor (Pnu) is connected to the pull down voltage supply source (Vssq). The drain of the p-channel pull down termination transistor (Pnu) is connected to the PVMI signal line (Qnu). The gate of the p-channel pull down termination transistor (Pnu) is connected to a bias voltage (VBnu). This voltage (Vbnu) is, in this example, independent of the output signal on Qnu, except for the coupling noise caused by the switching output signal. This p-channel pull down termination transistor (Pnu) is configured to pull the signal on Qnu toward a predefined voltage representing logic value “0” according to PVMI specifications such as HSTL or SSTL interface standards. When all the n-channel pull up single-transistors drivers (Nu1, Nu2, Nu3) are turned off by their switching gate signals (dnu1, dnu2, dnu3), the p-channel pull down termination transistor (Pnu) pulls Qnu toward a partial-voltage representing data value ‘0’ in the PVMI standard, such as the voltage (Vos) illustrated in FIG. 2(a). The driving capability of those n-channel pull up single-transistor drivers (Nu1, Nu2, Nu3) are calibrated to be compatible with existing PVMI signals. When one of the n-channel pull up transistors (Nu1, Nu2, Nu3) is turned on, the PVMI signal line (Qnu) is pulled toward a voltage representing data value ‘1’ in PVMI specification, such as the voltage (Voh) illustrated in FIG. 2(a). The p-channel pull down termination transistor (Pnu) is, in this example, shared by all the IC chips driving the same PVMI signal (Qnu). This p-channel pull down termination transistor (Pnu) can be placed inside one of the IC chips; it also can be an external circuit. It is also possible to have more than one complementary termination transistors connected to the same signal. The circuits in FIG. 7(a) consume little or no power when the output signal stays at ‘0’, but the circuits consume power when the output signal is switched to ‘1’. Because each output driver can be as simple as a single n-channel pull up transistor, the area of each output driver can be reduced significantly relative to alternative designs—achieving significant cost reduction. In this example, all of the n-channel pull up single-transistor output drivers (Nu1, Nu2, Nu3) will never pull against each other, so there is no bus contention problem—allowing the possibility of removing bus enable signals while still achieving higher performance.

While specific embodiments of the invention have been illustrated and described herein, it is realized that other modifications and changes will occur to those skilled in the art. The present invention is not limited to particular implementation discussed in the exemplary embodiments. For example, FIGS. 7(b-d) illustrate natural variations of the circuits in FIG. 7(a).

For the example in FIG. 7(b), an IC external PVMI signal (Qpd) is driven by p-channel pull down transistors (Pd1, Pd2, Pd3) as single-transistor output drivers in a separate IC chip. These single-transistor output drivers (Pd1, Pd2, Pd3) are configured as p-channel pull down transistors controlled by switching gate voltages (dpd1, dpd2, dpd3). The sources of these p-channel pull down transistors (Pd1, Pd2, Pd3) are connected to pull down voltage supply source (Vssq). The drains of these p-channel pull down transistors (Pd1, Pd2, Pd3) are connected to the PVMI signal line (Qdu). The data value of the PVMI signal (Qdu) is determined by switching gate signals (dpd1, dpd2, dpd3) of the p-channel pull down transistors (Pd1, Pd2, Pd3). These p-channel pull down transistors (Pd1, Pd2, Pd3) can only pull down the voltage on the IC external PVMI signal (Qpd). An n-channel pull up termination transistor (Npd) is therefore included to provide the pull up driving power. The source of the n-channel pull up termination transistor (Npd) is connected to the pull up voltage supply source (Vddq). The drain of the n-channel pull up termination transistor (Npd) is connected to the PVMI signal line (Qpd). The gate of the n-channel pull up termination transistor (Npd) is connected to a bias voltage (VBpd). This voltage (VBpd) is, in this example, independent of the output signal on Qpd, except for the coupling noise caused by the switching output signal. This n-channel pull up termination transistor (Npd) is configured to pull the signal on Qpd toward a predefined voltage representing logic value “1” according to the PVMI specifications such as HSTL or SSTL interface standards. When all the p-channel pull down single-transistors drivers (Pd1, Pd2, Pd3) are turned off by their switching gate signals (dpd1, dpd2, dpd3), the n-channel pull up termination transistor (Npd) pulls Qpd toward a partial-voltage representing data value ‘1’ in the PVMI standard, such as the voltage (Voh) illustrated in FIG. 2(a). The driving capability of those p-channel pull down single-transistor drivers (Pd1, Pd2, Pd3) are calibrated to be compatible with existing PVMI signals. When one of the p-channel pull down transistors (Pd1, Pd2, Pd3) is turned on, the PVMI signal line (Qpd) is pulled toward a voltage representing data value ‘0’ in the PVMI specification, such as the voltage (Vos) illustrated in FIG. 2(a). The n-channel pull up termination transistor (Npd) is, in this example, shared by all the IC chips driving the same PVMI signal (Qpd). This n-channel pull up termination transistor (Npd) can be placed inside one of the IC chips; it also can be an external circuit. It is also possible to have more than one complementary termination transistor connected to the same signal. The circuits in FIG. 7(b) consume little or no power when the output signal stays at ‘1’, but the circuits consume power when the output signal is switched to ‘0’. Because each output driver can be as simple as a single p-channel pull down transistor, the area of each output driver can be reduced significantly relative to alternative designs—achieving significant cost reduction. All the p-channel pull down single-transistors drivers (Pd1, Pd2, Pd3) will never pull against each other, so there is no bus contention problem—allowing the possibility of removing bus enable signals while still achieving higher performance.

For the example in FIG. 7(c), an IC external PVMI signal (Qpu) is driven by p-channel pull up transistors (Pu1, Pu2, Pu3) as single-transistor output drivers in a separate IC chip. These single-transistor output drivers (Pu1, Pu2, Pu3) are configured as p-channel pull up transistors controlled by switching gate voltages (dpu1, dpu2, dpu3). The sources of these p-channel pull up transistors (Pu1, Pu2, Pu3) are connected to pull up voltage supply source (Vddq). The drains of these p-channel pull up transistors (Pu1, Pu2, Pu3) are connected to the PVMI signal line (Qpu). The data value of the PVMI signal (Qpu) is determined by switching gate signals (dpu1, dpu2, dpu3) of the p-channel pull up transistors (Pu1, Pu2, Pu3). These p-channel pull up transistors (Pu1, Pu2, Pu3) can only pull up the voltage on the IC external PVMI signal (Qpu). A p-channel pull down termination transistor (Pnu) is therefore included to provide the pull down driving power. The source of the p-channel pull down termination transistor (Pnu) is connected to the pull down voltage supply source (Vssq). The drain of the p-channel pull down termination transistor (Pnu) is connected to the PVMI signal line (Qpu). The gate of the p-channel pull down termination transistor (Pnu) is connected to a bias voltage (VBnu). This voltage (Vbnu) is, in this example, independent of the output signal on Qpu, except for the coupling noise caused by the switching output signal. This p-channel pull down termination transistor (Pnu) is configured to pull the signal on Qpu toward a predefined voltage representing logic value “0” according to the PVMI specifications such as HSTL or SSTL interface standards. When all the p-channel pull up single-transistor drivers (Pu1, Pu2, Pu3) are turned off by their switching gate signals (dpu1, dpu2, dpu3), the p-channel pull down termination transistor (Pnu) pulls Qpu toward a partial-voltage representing data value ‘0’ in the PVMI standard, such as the voltage (Vos) illustrated in FIG. 2(a). The driving capability of those p-channel pull up single-transistor drivers (Pu1, Pu2, Pu3) are calibrated to be compatible with existing PVMI signals. When one of the p-channel pull up transistors (Pu1, Pu2, Pu3) is turned on, the PVMI signal line (Qpu) is pulled toward a voltage representing data value ‘1’ in PVMI specification, such as the voltage (Voh) illustrated in FIG. 2(a). The p-channel pull down termination transistor (Pnu) is, in this example, shared by all the IC chips driving the same PVMI signal (Qpu). This p-channel pull down termination transistor (Pnu) can be placed inside one of the IC chips; it also can be an external circuit. It is also possible to have more than one complemented termination transistor connected to the same signal. The circuits in FIG. 7(c) consume little or no power when the output signal stays at ‘0’, but the circuits consume power when the output signal is switched to ‘1’. Because each output driver can be as simple as a single p-channel pull up transistor, the area of each output driver can be reduced significantly relative to alternative designs—achieving significant cost reduction. All the p-channel pull up single-transistors drivers (Pu1, Pu2, Pu3) will never pull against each other, so there is no bus contention problem—allowing the possibility of removing bus enable signals while achieving higher performance.

For the example in FIG. 7(d), an IC external PVMI signal (Qnd) is driven by n-channel pull down transistors (Nd1, Nd2, Nd3) as single-transistor output drivers in a separate IC chip. These single-transistor output drivers (Nd1, Nd2, Nd3) are configured as n-channel pull down transistors controlled by switching gate voltages (dnd1, dnd2, dnd3). The sources of these n-channel pull down transistors (Nd1, Nd2, Nd3) are connected to pull down voltage supply source (Vssq). The drains of these n-channel pull down transistors (Nd1, Nd2, Nd3) are connected to the PVMI signal line (Qnd). The data value of the PVMI signal (Qnd) is determined by switching gate signals (dnd1, dnd2, dnd3) of the n-channel pull down transistors (Nd1, Nd2, Nd3). These n-channel pull down transistors (Nd1, Nd2, Nd3) only can pull down the voltage on the IC external PVMI signal (Qnd). An n-channel pull up termination transistor (Npd) is therefore included to provide the pull up driving power. The source of the n-channel pull up termination transistor (Npd) is connected to the pull up voltage supply source (Vddq). The drain of the n-channel pull up termination transistor (Npd) is connected to the PVMI signal line (Qnd). The gate of the n-channel pull up termination transistor (Npd) is connected to a bias voltage (VBpd). This voltage (VBpd) is, in this example, independent of the output signal on Qnd, except for the coupling noise caused by the switching output signal. This n-channel pull up termination transistor (Npd) is configured to pull the signal on Qnd toward a predefined voltage representing logic value “1” according to the PVMI specifications such as HSTL or SSTL interface standards. When all the n-channel pull down single-transistors drivers (Nd1, Nd2, Nd3) are turned off by their switching gate signals (dnd1, dnd2, dnd3), the n-channel pull up termination transistor (Npd) pulls Qnd toward a partial-voltage representing data value ‘1’ in the PVMI standard, such as the voltage (Voh) illustrated in FIG. 2(a). The driving capability of those n-channel pull down single-transistor drivers (Nd1, Nd2, Nd3) are calibrated to be compatible with existing PVMI signals. When one of the n-channel pull down transistors (Nd1, Nd2, Nd3) is turned on, the PVMI signal line (Qnd) is pulled toward a voltage representing data value ‘0’ in the PVMI specification, such as the voltage (Vos) illustrated in FIG. 2(a). The n-channel pull up termination transistor (Npd) is, in this example, shared by all the IC chips driving the same PVMI signal (Qnd). This n-channel pull up termination transistor (Npd) can be placed inside one of the IC chips; it also can be an external circuit. It is also possible to have more than one complementary termination transistor connected to the same signal. The circuits in FIG. 7(d) consume little or no power when the output signal stay at ‘1’, but the circuits consume power when the output signal is switched to ‘0’. Because each output driver can be as simple as a single n-channel pull down transistor, the area of each output driver can be reduced significantly relative to alternative designs—achieving significant cost reduction. All the n-channel pull down single-transistors drivers (Nd1, Nd2, Nd3) will never pull against each other, so there is no bus contention problem—allowing the possibility of removing bus enable signals while achieving higher performance.

The output drivers of the preferred embodiments of the present invention, including but not limited to the examples illustrated in FIGS. 3(a-i), 4(a-f), 5(a-c), 6, 7(a-d), can support many existing small signal interfaces with compatible signal levels while achieving high performance with power/cost savings. Table 2 lists a few examples of potential applications.

TABLE 2

| | voltage | Data rate | Typical |
|---|---|---|---|
| Applications | levels (#) | (bits/second) | Applications |
| HSTL SRAM interface | 2 | 666M | SRAM |
| SSTL DRAM interface | 2 | 400-1600M | DRAM |
| GTL or BTL logic interface | 2 | 100-1600M | Microprocessors, |
| | | | chip-set, |
| | | | graphic IC, |
| | | | communication. |
| 4-level SAI interface | 4 | 2G | |
| 8-level SAI interface | 8 | 3G | |
| LCD driver | 64 | ~72K | Cellular phone |
| RGB display | 256 | ~480M | display |

The numbers listed in table 2 are exemplary only; the actual characteristics will change with based upon the application.

While specific embodiments of the invention have been illustrated and described herein, it is realized that other modifications and changes will occur to those skilled in the art. The present invention is not limited to particular implementation discussed in specific examples. For example, the immediately above examples are all single-ended signal drivers while output drivers of the present invention are excellent in driving differential signals.

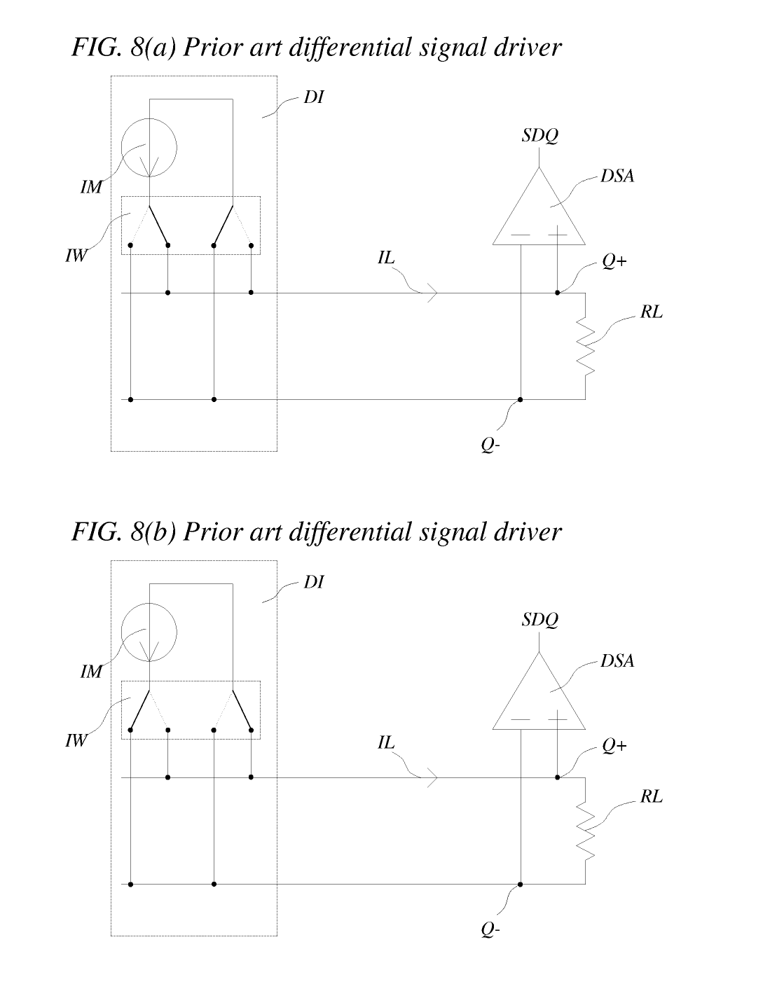

Differential signaling is a method of transmitting information electrically using two complementary signals sent on two separated conductors with matched properties. FIGS. 8(a, b) are simplified symbolic diagrams illustrating the operational principles of typical differential signal drivers. In FIGS. 8(a, b), a pair of differential signal lines (Q+, Q−) are driven by a differential output driver (DI). A load resistor (RL) is connected between Q+ and Q−. This load resistor typically also serves the function of a termination resistor helping to reduce signal reflection for transmission lines. The voltages on Q+ and Q− are sensed by a differential sense amplifier (DSA). A typical differential signal output driver (DI) can be represented by an equivalent circuit that comprises current source (IM) and switches (IW). To drive a binary data 1, the switches (IW) are configured as shown in FIG. 8(a) where the driver (DI) drives a current (IL) flowing from Q+ through RL to Q−. Since the voltage of Q+ is higher than the voltage of Q− under this configuration, the output (SDQ) of the differential sense amplifier (DSA) is binary data 1. To drive a binary data 0, the switches (IW) are configured as shown in FIG. 8(b) where the driver (DI) drives a current (IL) flowing from Q− through RL to Q+. Since the voltage of Q+ is lower than the voltage of Q− in this configuration, the output (SDQ) of the differential sense amplifier (DSA) is binary data 0. By controlling the status of those switches (IW), switching differential signals can be transferred by the output driver (DI).

The most important advantage of differential signaling is noise tolerance. Differential sense amplifiers (DSA) are typically designed to have excellent common mode noise rejection. Differential signal transfer systems are therefore capable of transferring data under noisy conditions if the major noise sources are common mode noises such as coupling noises or shifting in power/ground voltages. However, differential signal transfer systems are typically sensitive to resistance/inductance on the signal lines (Q+, Q−) or differential mode noises; they also have problems in driving signal lines with heavy capacitance loading because of the constraint in driving current.

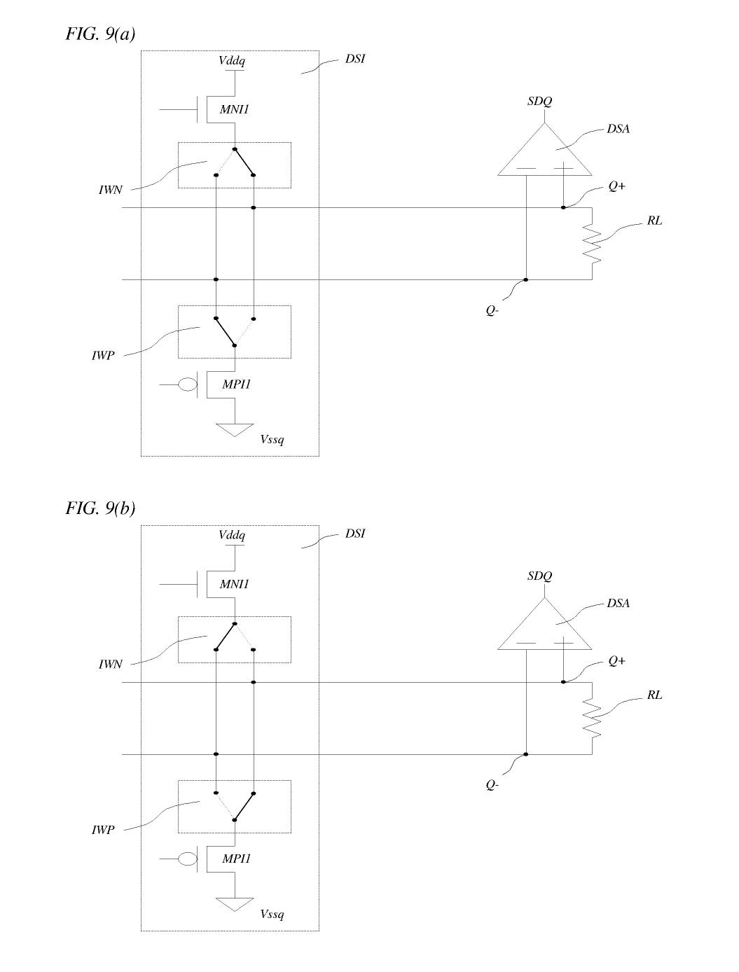

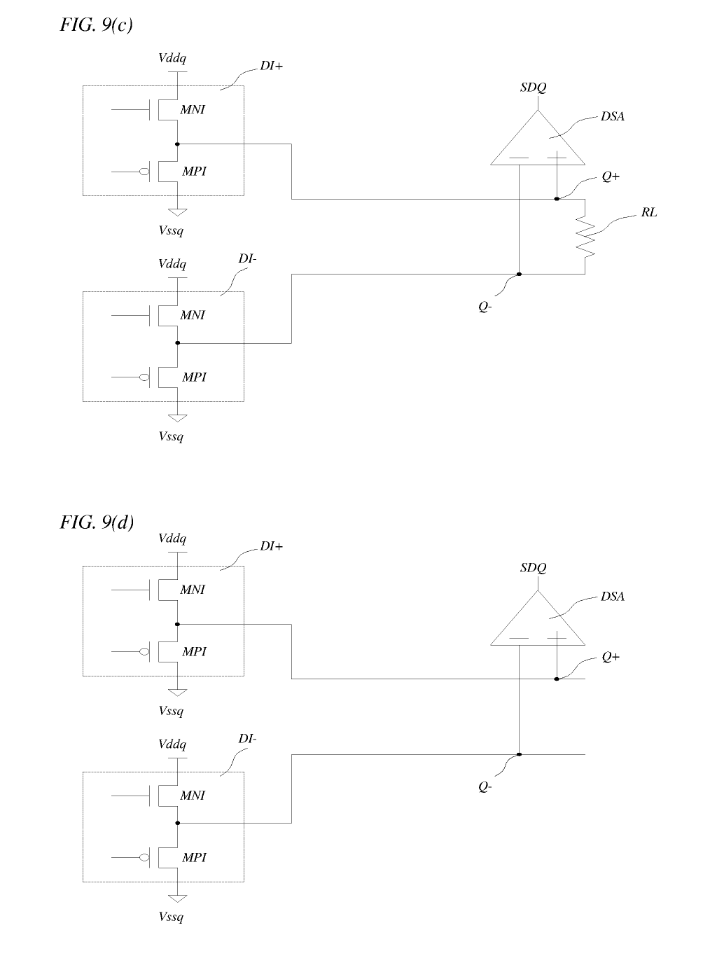

Output drivers of the preferred embodiments of the present invention are excellent at driving differential signals. FIGS. 9(a-d) show simplified examples of differential signal output drivers of the preferred embodiments of the present invention. For the examples shown in FIGS. 9(a,b), a differential signal output driver (DSI) comprises n-channel pull up transistor (MNI1), p-channel pull down transistor (MPI1) and switches (IWN, IWP). Using the naming convention provided in FIG. 3(a), the n-channel pull up transistor (MNI1) is biased to drive the signal line to a higher partial voltage Voh, while the p-channel pull down transistor is biased to drive the signal to a lower partial voltage Vos. Because the methods to control the output voltages of the single-end drivers discussed previously are also applicable for differential output drivers, the prior explanation as to how to generate those partial voltages is applicable here as well. To drive a binary data 1, the switches (IWN, IWP) are configured as shown in FIG. 9(a), so that a positive differential voltage (Voh−Vos) is driven on the differential signal pair (Q+, Q−). The output (SDQ) of the differential sense amplifier (DSA) is therefore binary data 1. To drive a binary data 0, the switches (IWN, IWP) are configured as shown in FIG. 9(b), so that a negative differential voltage (Vos−Voh) is driven on the differential signal pair (Q+, Q−). The output (SDQ) of the differential sense amplifier (DSA) is therefore binary data 0. By controlling the states of the switches (IWN, IWP), switching differential signals can be driven by the output driver (DSI). The switches (IWN, IWP) can be configured to drive high impedance, both-zero, and both-one states.

While specific embodiments of the invention have been illustrated and described herein, it is realized that other modifications and changes will occur to those skilled in the art. The present invention is not limited to particular implementations discussed in specific examples. There are wide varieties of methods to design differential signal output drivers. For example, FIG. 9(c) illustrates a method that uses a single-end output driver (DI+) of the preferred embodiments of the present invention to drive Q+, while using another single-end output driver (DI−) of the preferred embodiments of the present invention to drive Q−. Switching differential signals are driven by switching the input signals of both output drivers (DI+, DI−). The n-channel pull up transistor used by differential output drivers of the preferred embodiments of the present invention can be enhanced mode, depletion mode, or native transistors. The p-channel pull down transistor used by differential output drivers of the preferred embodiments of the present invention also can be enhanced mode, depletion mode, or native transistors.

Using output drivers of the preferred embodiments of the present invention, it is possible to remove the loading resistor (RL) while the voltages on the differential signal lines (Q+, Q−) still meet the requirements of differential signal interface specifications. FIG. 9(d) shows driver configurations that are the same as the configurations in FIG. 9(c) except the system no longer uses the resistor RL. Similarly, the load resistor RL can be removed for the examples shown in FIGS. 9(a, b) while still satisfying the requirements of various differential interface protocols.

Differential signal output drivers of the preferred embodiments of the present invention have many advantages over typical differential signal output drivers. The driving power of typical differential signal output drivers are limited by the loading resistor (RL) because IL*RL equals the voltage drop limited by the specification of signal transfer protocols. This limitation in driving power limits the performance of prior differential signal drivers. The output voltages of the drivers of the preferred embodiments of the present invention are weakly dependent on RL so the driving capability can be scaled to achieve better performance. Typical current mode differential signal output drivers consume power even when the outputs are not switching. The differential output drivers of the preferred embodiments of the present invention provide the option to remove loading resistors to save power. Typical differential signal output drivers can not support large fan-out configurations that require multiple termination resistors. A differential output driver of the preferred embodiments of the present invention can support large fan-out because its output voltage is not sensitive to the size of termination resistors. Likewise, typical differential signal output drivers are sensitive to parasitic resistance or leakage current on the signal lines, while differential signal output drivers of the preferred embodiments of the present invention are not sensitive to parasitic resistance or leakage current. Differential signal output drivers of the preferred embodiments of the present invention have the same common mode noise rejection as typical different output drivers, while the preferred embodiments of the present invention provide better tolerance to differential noises.

There are wide varieties of applications for differential signal output drivers of the present invention, including but not limited to the examples shown in FIGS. 9(a-d). Typical examples for the application of differential signal output drivers of the present invention are listed in Table 3.

TABLE 3
application examples

| Interface protocol | Typical Applications |
|---|---|
| SSTL clock | DDR DRAM interface clock signals |
| SATA | Mass storage devices |
| PCIe | Computer expansion cards |
| LVDS | Graphic interface, communication. |
| MIPI | Mobile devices |
| MDDI | Mobile devices |

The Stub Series Terminated Logic (SSTL) interfaces commonly used for DRAM interfaces have gone through three generations of evolution. The SSTL2 standard is commonly used for double data rate version 1 (DDRI) DRAM's with power supply voltage at 2.5 volts. The SSTL_{—}18 standard is commonly used for double data rate version 2 (DDRII) DRAM's with power supply voltage at 1.8 volts. The SSTL_{—}15 standard is commonly used for double data rate version 3 (DDR3) DRAM's with power supply voltage at 1.5 volts. As discussed previously, for SSTL interfaces the data and control signals are single-ended signals centered at a reference voltage at half of the power supply voltage. However, the clock signals for SSTL interface are differential signals. Drivers of the preferred embodiments of the present invention are not only ideal to drive SSTL data/control signals but also ideal to drive SSTL clock signals. These and future generations of SSTL interfaces can achieve significant power savings and performance improvements using output drivers of the preferred embodiments of the present invention.

The “Serial Advanced Technology Attachment” (SATA) computer bus, is a storage-interface for connecting host bus adapters to mass storage devices such as hard disk drives and optical drives. The SATA host adapter is integrated into almost all modern consumer laptop computers and desktop motherboards. The first generation of SATA interface supports 1.5 billion bits per second (GBPS), the second generation SATA interface supports 3 GBPS, and the third generation supports 6 GBPS.

The “Peripheral Component Interconnect Express” (PCIe) interface is a computer expansion card standard. The PCIe interface is used in consumer, server, and industrial applications, as a motherboard-level interconnect (to link motherboard-mounted peripherals) and as an expansion card interface for add-in boards. A key difference between PCIe and earlier buses is a topology based on point-to-point serial links, rather than a shared parallel-bus architecture.

The Low Voltage Differential Signal (LVDS) interfaces are developed for signal transfers at a distance up to 30 feet. The original generation of LVDS supports one-to-one signal transfers. Latter generations of LVDS support many-to-many data transfers. The LVDS interfaces are widely used for applications such as graphic interfaces for large flat panel display, automobile signal transfers, and communication back panel signal transfers. Output drivers of the preferred embodiments of the present invention can save power, increase fan-in/fan-out and improve performance of LVDS interface devices.

The Mobile Industry Processor Interface (MIPI) and the Mobile Display Digital Interface (MDDI) are similar interface protocols developed for mobile devices. The major purpose for MIPI/MDDI interfaces is to simplify routing for circuit boards used for mobile devices such as cellular phones. Interface signals between different IC chips used by mobile devices are serialized by the drivers then de-serialized by the receivers. The operational principles of MIPI/MDDI interfaces are similar to LVDS while they typically support short distance signal transfers. Power saving is certainly one of the most important design considerations for mobile devices. Differential signal output drivers of the preferred embodiments of the present invention can help in saving power while also improving performance for the MIPI/MDDI output drivers.

A differential signal output driver, by definition, is the last-stage circuit in an IC that provide the majority of the current driving force (while turned on) to drive a pair of external differential signals. Differential signal output drivers of the preferred embodiments of the present invention drive switching partial voltages to external differential signal lines. Although the output voltages driven by differential signal output drivers of the preferred embodiments of the present invention are partial voltages with amplitude between the power supply voltage (Vddq) and ground voltage (Vssq) at the driver end, the voltage may be out of power supply ranges at receiver ends due to power/ground level shifting or coupling noises. For purposes of the present invention, such signals are still partial voltage signals as long as the difference of the voltages on the differential signal lines is a partial voltage.

While specific embodiments of the invention have been illustrated and described herein, it is realized that other modifications and changes will occur to those skilled in the art. The scope of the present invention is not limited by specific examples.

Typical output drivers rely on termination resistors to generate partial voltage signals. Output drivers of the preferred embodiments of the present invention can support the same signal voltage levels following HSTL, SSTL, GTL, BTL, SATA, PCIe, LVDS, MIPI, MDDI, or other standards without using termination resistors, thereby achieving better performance while consuming less power. Driving without termination circuits by using output drivers of the present invention works very well when the signal lines are short. However, when the signal line is long, drivers of the preferred embodiments of the present invention may need termination circuits to reduce reflection induced signal distortion. It is well known to the art of circuit design that when the propagation delay time along an electrical line is comparable to the rise/fall time of the electrical signals driven on it, the electrical line behaves as a transmission line and electrical signals behave as waves. The reflection of the signal waveform near the end of a transmission line can cause significant signal distortion. It is also well known to the art that termination circuits with impedance equivalent to the characteristic impedance (Zo) of the transmission line can reduce reflection effects.

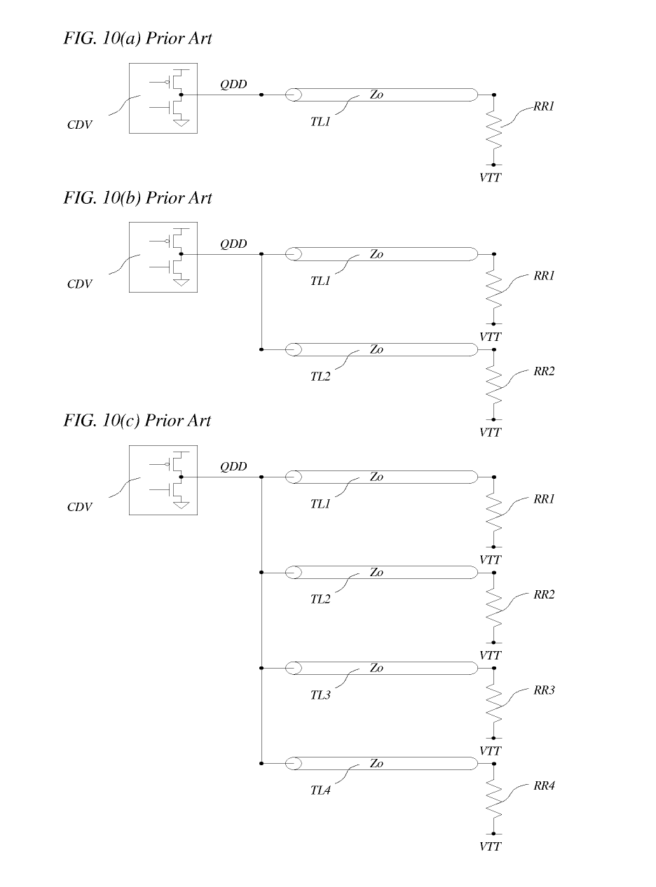

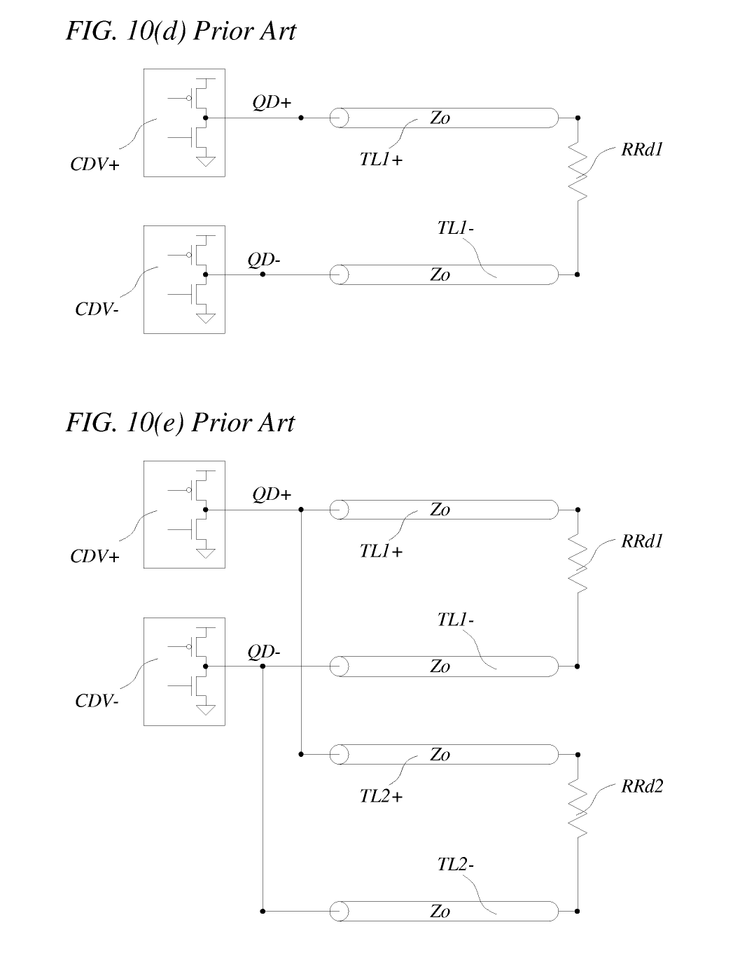

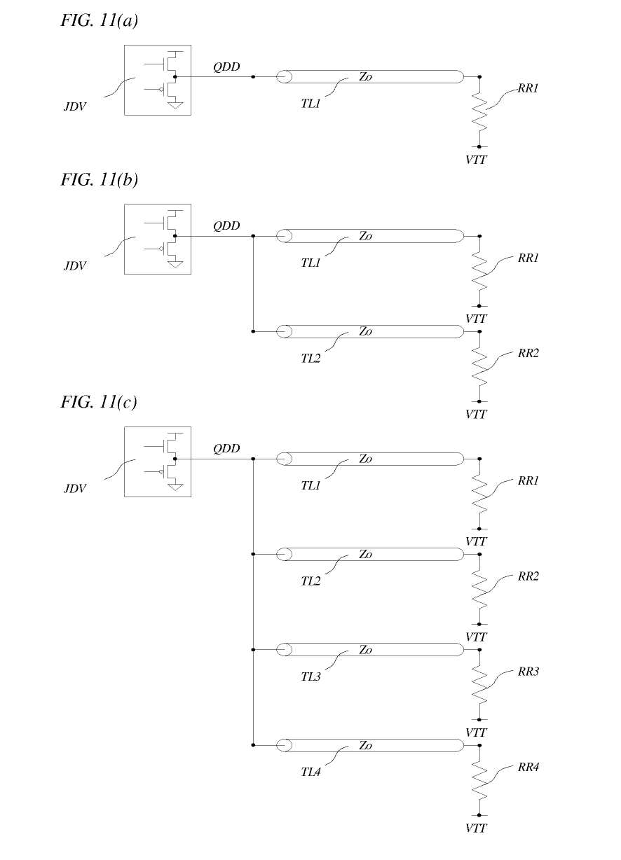

FIG. 10(a) is a simplified symbolic view showing a typical output driver (CDV) driving a signal (QDD) on a transmission line (TL1) that has characteristic impedance Zo. For simplicity, the output driver (CDV) in FIGS. 10(a-d) is represented symbolically by a driver with p-channel pull up transistor and n-channel pull down transistor. This simplified symbolic view is meant to represent various known drivers that may have more complex structures. In FIG. 10(a), a termination resistor (RR1) is placed near the end of the transmission line (TL1) to reduce reflection effects. In this example, the termination resistor (RR1) is represented symbolically by a single resistor connected to a single voltage source (VTT), while actual termination circuits can be more complex. It is well known to the art that signal reflection is minimized when the value of the termination resistor (RR1) is adjusted to be about equal to the characteristic impedance (Zo) of the transmission line (TL1). The characteristic impedances (Zo) of signal lines on printed circuit boards (PCB) are typically configured between 40 and 120 Ohms. For simplicity, the following exemplary discussions will use a common value of 50 Ohms as Zo. An output driver should provide enough current to drive the termination resistor (RR1) to reach signal amplitude according to the applicable specification. In the mean time, an output driver should not provide too much current, otherwise the amplitudes of output signals will be out of specification. The driving capabilities of small signal interface output drivers are therefore confined. Different versions of small signal interfaces, such as HSTL, SSTL, GTL, BTL, SATA, PCIe, LVDS, MIPI, MDDI or others, define the signal amplitudes at various values. For simplicity, in the following discussions a medium value of 500 milli-Volts (mV) will be used as the defined signal amplitude in our discussions. For example, the known output driver (CDV) in FIG. 10(a) should be adjusted to drive about 10 milli-Amps (mA) in order to provide a 500 mV signal on a transmission line connected to a 50 Ohm termination resistor. The output driver also can not drive much higher than 10 mA; otherwise the signal amplitude will be too large, causing performance degradation. The driving strength of the output driver is therefore confined within a narrow range.

Typical small signal output drivers have problems driving more than one transmission lines. FIG. 10(b) shows the situation when the output driver (CDV) in FIG. 10(a) is used to drive another transmission line (TL2) that is terminated with other termination resistors (RR2). The last stage transistors in typical output drivers often operate under saturation region at fixed gate-to-source voltage. That means the driving strength of such output drivers remain about the same when loading is changed. Under this situation, the steady-state signal amplitude will be reduced by half when such an output driver needs to drive two termination resistors (RR1, RR2). FIG. 10(c) shows the situation when the output driver (CDV) in FIG. 10(a) drives 4 transmission lines (TL1-TL4) with termination resistors (RR1-RR4) that match Zo. Under this situation, the steady-state signal amplitude driven by the output driver (CDV) will be reduced to ˜¼ of standard amplitude, as shown by the simplified examples in Table 4. This problem is referred to herein as the “fan out problem”.

Commonly used differential output drivers also have a similar fan out problem. FIG. 10(d) is a simplified symbolic view showing a pair of known differential signal drivers (CDV+, CDV−) driving differential signal pair (QD+, QD−) along a pair of transmission lines (TL1+, TL1−) with characteristic impedance Zo. For simplicity, these output drivers (CDV+, CDV−) are represented symbolically by drivers with p-channel pull up transistor and n-channel pull down transistor while the actual output driver can be more complex. A termination resistor (RRd1) is placed near the ends of the transmission lines (TL1+, TL1−) to reduce reflection effects. It is well known to the art that the value of the termination resistor (RRd1) for differential signals should be adjusted to be about equal to 2*Zo to achieve optimum anti-reflection effects. For example, if Zo is 50 Ohms, the value of the termination resistor (RRd1) should be around 100 Ohms. That means the known output driver pair (CDV+, CDV−) should be adjusted to provide 5 mA of current to support 500 mV in differential signal amplitude. FIG. 10(e) is a simplified symbolic view showing the same differential signal output drivers (CDV+, CDV−) driving an additional pair of transmission lines (TL2+, TL2−) with another termination resistor (RRd2). For similar reasons as the output driver in FIGS. 10(b), the signal amplitude will be reduced by half for the situation in FIG. 10(e). Known differential output drivers also have fan out problems.

The last stage transistors in known output drivers often operate in the saturation region at fixed gate-to-source voltage. That means the driving strength of such output drivers remain about the same when the load is changed. To solve the fan out problem, it has proved necessary in the past to increase the size of (or use multiple of) these output drivers to drive multiple transmission lines. For example, one could use two output drivers to drive two transmission lines, or use four output drivers to drive four transmission lines.

The last stage transistors in the output drivers of the preferred embodiments of the present invention are n-channel pull up transistor(s) and/or p-channel pull down transistor(s). Those transistors typically follow the square rules shown in EQ 1 and/or EQ 2. In other words, output drivers of the preferred embodiments of the present invention will automatically increase driving current to approach target voltage amplitude when the load changes. Therefore, output drivers of the preferred embodiments of the present invention are capable of solving the fan out problem.

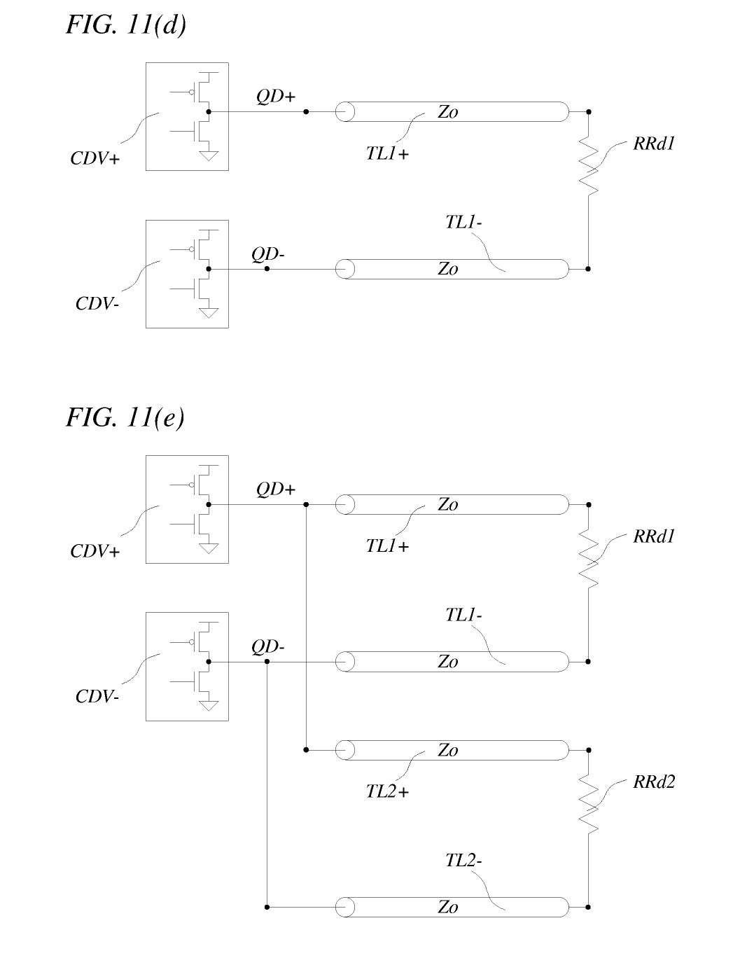

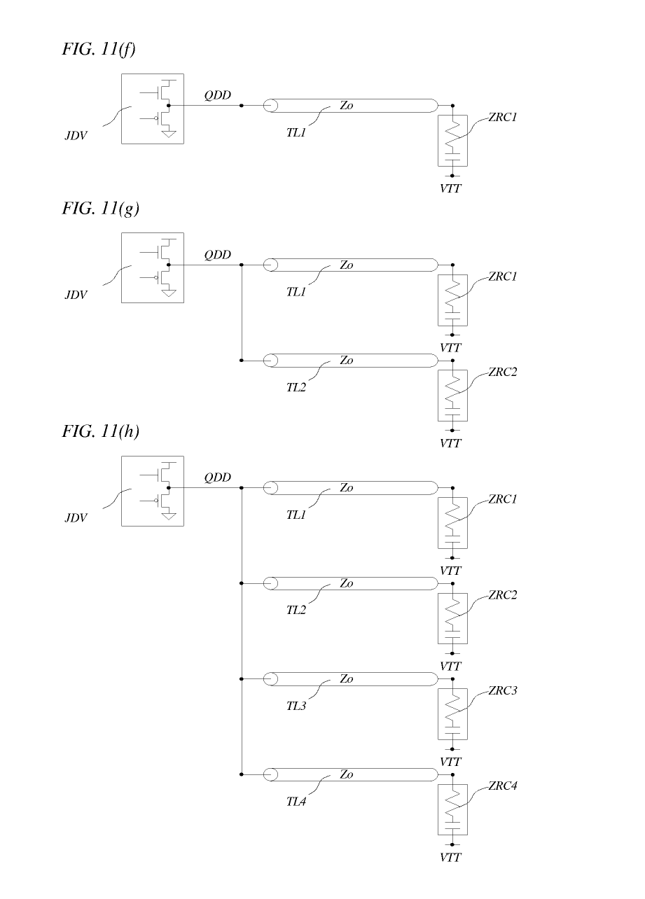

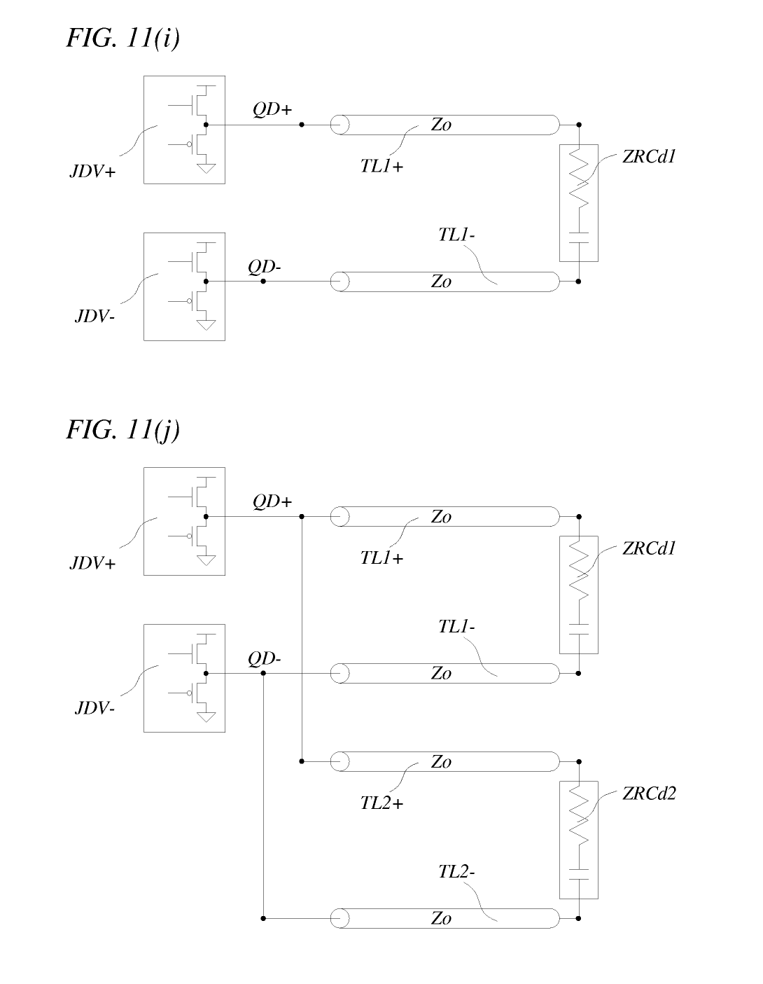

FIG. 11(a) is a simplified symbolic view showing an output driver (JDV) of the present invention driving the same signal (QDD), transmission line (TL1), and termination resistor (RR1) as those in FIG. 10(a). For simplicity, the output drivers (JDV, JDV+, JDV−) of the present invention in FIGS. 11(a-j) are represented symbolically by a driver with n-channel pull up transistor and p-channel pull down transistor. This simplified symbolic view is meant to represent various output drivers of the present invention that may have more complex structures, such as those disclosed in this patent application. FIG. 11(b) shows the output driver of FIG. 11(a) driving two transmission lines (TL1, TL2) and two termination resistors (RR1, RR2) that are the same as those in FIG. 10(b). FIG. 11(c) shows the output driver of FIG. 11(a) driving four transmission lines (TL1-TL4) and four termination resistors (RR1-RR4) that are the same as those in FIG. 10(c). Because the output driver transistors of the preferred embodiments of the present invention are n-channel pull up transistor(s) and/or p-channel pull down transistor(s) that typically follow the square rules shown in EQ 1 and/or EQ 2, the output drivers of the preferred embodiments of the present invention will automatically increase driving current to approach target voltage amplitude when the load changes. For example, if the size of an output driver of the preferred embodiments of the present invention is adjusted to drive 11 mA of current for the situation in FIG. 11(a), the quiescent state amplitude of the signal would be 550 mV. When the same output driver (JDV) drives two transmission lines as shown by the situation in FIG. 11(b), the voltage amplitude will drop by about 50 mV to double the driving current, and when the same output driver (JDV) drives 4 transmission lines as shown by the situation in FIG. 11(c), the voltage amplitude will drop by about another 50 mV to quadruple the current, as shown by the examples listed in Table 4. Therefore, output drivers of the preferred embodiments of the present invention offer the flexibility of driving multiple transmission lines while still meeting signal amplitude requirements without changing the size of the output drivers. Numbers used in our examples are oversimplified estimation while the exact numbers are complex functions of actual operating conditions.

Similar principles are applicable to differential output drivers of the preferred embodiments of the present invention. FIG. 11(d) is a simplified symbolic view showing a pair of differential output drivers (CDV+, CDV−) of the present invention driving the same pair of transmission lines (TL1+, TL1−) and termination resistor (RRd1) as those in FIG. 10(d). For simplicity, the differential output drivers (CDV+, CDV−) are represented symbolically by drivers with n-channel pull up transistor and p-channel pull down transistor while the actual output driver can be more complex. FIG. 11(e) is a simplified symbolic view showing the same pair of differential output drivers (CDV+, CDV−) of the present invention driving the same two pairs of transmission lines (TL1+, TL1−, TL2+, TL2−) and termination resistor (RRd1, RRD2) as those in FIG. 10(e). For similar reasons, the differential output drivers of the preferred embodiments of the present invention will be able to drive multiple transmission lines with tolerable drops in signal amplitude.

While specific embodiments of the invention have been illustrated and described herein, it is realized that other modifications and changes will occur to those skilled in the art. The scope of the present invention is not limited by specific examples. The simplified examples in FIGS. 11(a-e) illustrate the capabilities of output drivers of the preferred embodiments of the present invention to solve the fan out problem of known small signal output drivers. However, the circuits in FIGS. 11(a-e) would consume about the same power as known output drivers. FIGS. 11(f-j) illustrates methods to achieve power saving while maintaining compatibility with small signal interfaces such as HSTL, SSTL, GTL, BTL, SATA, PCIe, LVDS, MIPI, MDDI, or other standards.

The circuits shown in FIG. 11(f) are nearly identical to those shown in FIG. 11(a) except that the termination resistor (RR1) in FIG. 11(a) is replaced by an RC termination circuit (ZRC1). Similarly, the circuits shown in FIG. 11(g-i) are nearly identical to those shown in FIGS. 11(b-e) except that the termination resistors (RR1-RR4, RRd1-RRd2) are replaced by RC termination circuits (ZRC1-ZRC4, ZRCd1-ZRCd2). Those RC termination circuits (ZRC1-ZRC4, ZRCd1-ZRCd2) are represented symbolically by a resistor connected in series with a capacitor, but the actual implementation can be more complex. It is well known to the art that signal reflection can be reduced if the termination circuit of a transmission line has an impedance about equal to the characteristic impedance (Zo) of the transmission line. This termination impedance does not have to be resistive. Other components, such as capacitor(s), can be added for anti-reflection purposes at the operation range of target applications. For example, to support DDR2 SSTL standard at 800M bits per second, a 40 Ohm resistor with a 50 pf capacitor can serve as an effective termination circuit. The resulting RC termination circuit has an effective impedance near 50 Ohms when the signals on the transmission lines are switching, and the effective impedance approaches that of the capacitor at low frequency to allow power saving. The actual capacitor and resistor values may vary with different operating conditions while the RC termination circuits also can have different designs. When the transmission line (TL1) is terminated with RC termination circuit instead of termination resistor (RR1) as shown by the examples in FIGS. 11(f-i), output drivers of the preferred embodiments of the present invention consume little power at quiescent state while signal reflection is minimized by the RC termination circuit. Another advantage of using RC termination circuits is that the steady-state signal amplitude would be nearly independent of fan out for multiple transmission lines driven by output drivers of the preferred embodiments of the present invention as shown by the examples in Tables 4, 5.

The numbers listed in Table 4 and Table 5 are simplified examples. The exact numbers of course vary in different applications.

TABLE 4
comparison in fan out versus quiescent state signal amplitudes

| | known output | Exemplary output | Exemplary output |
|---|---|---|---|
| | driver using | driver of the present | driver of the present |
| Fan | termination | invention using | invention using RC |
| out | resistor | termination resistor | termination circuit |
| 1 | 500 mV | 550 mV | 550 mV |
| 2 | 250 mV | 500 mV | 550 mV |
| 4 | 125 mV | 450 mV | 550 mV |

TABLE 5
Partial voltage output driver quiescent state current as a function
of the number of termination circuits driven by the output driver.

| Number of | Known output driver | Exemplary output driver of |
|---|---|---|
| termination | using 50 Ohm termi- | the present invention using |
| circuits | nation resistors | RC termination circuits |
| 1 | 11 mA | smaller than 0.01 mA |
| 2 | 22 mA | smaller than 0.01 mA |
| 4 | 44 mA | smaller than 0.01 mA |

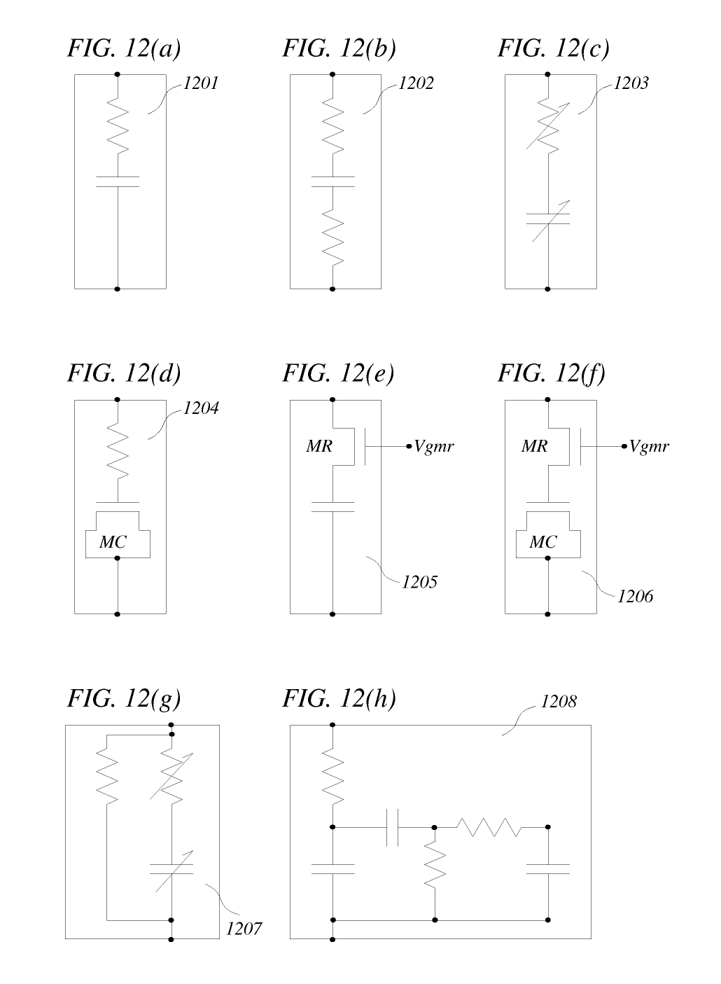

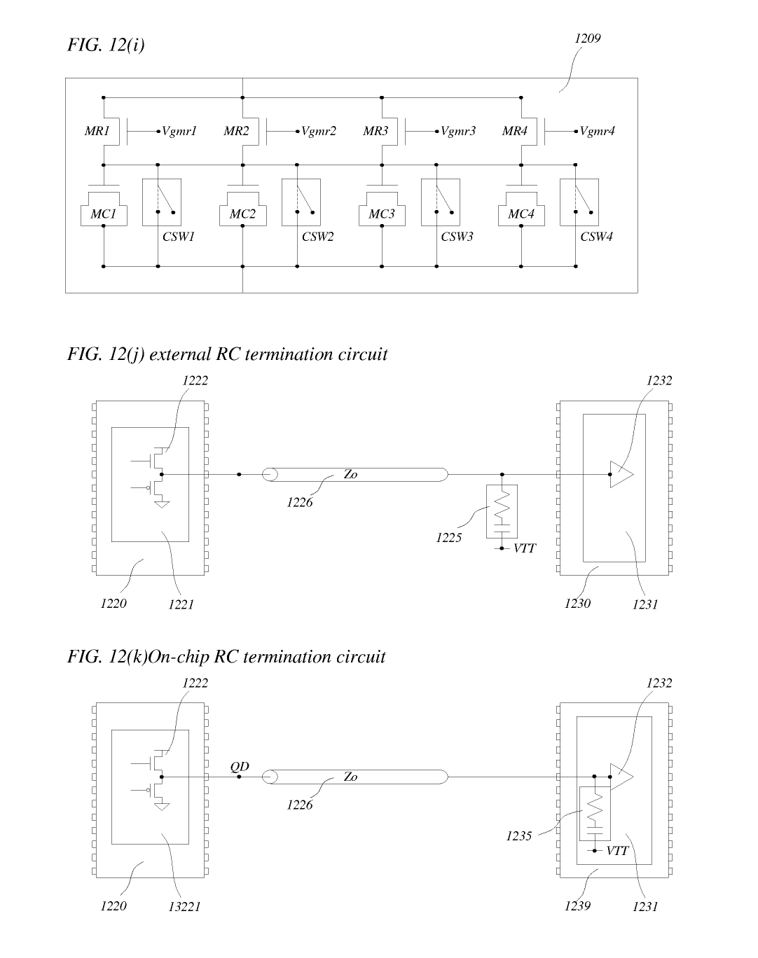

An RC termination circuit of the preferred embodiments of the present invention, by definition, is (1) an anti-refection circuit, (2) an equivalent circuit with impedance near the characteristic impedance (Zo) of the transmission line at specified operation frequencies of target small signal interface, and (3) an equivalent circuit with high impedance at low frequencies. Examples of RC termination circuits are shown by the symbolic views in FIGS. 12(a-i). FIG. 12(a) shows an RC termination circuit (1201) that comprises one resistor (RCR) and one capacitor (RCC). FIG. 12(b) shows an RC termination circuit (1202) that comprises two resistors (RCR1, RCR2) and one capacitor (RCC2). FIG. 12(c) shows an RC termination circuit (1203) that comprises one variable resistor (RCRv) and one variable capacitor (RCCc). The flexibility to adjust capacitor and/or resistor values can broaden the range of operating conditions. The resistors and/or capacitors can be implemented by a wide variety of equivalent circuits. FIG. 12(d) shows an example when an RC termination circuit (1204) uses a transistor (MC) to serve as a capacitor. FIG. 12(e) shows an example when an RC termination circuit (1205) uses a transistor (MR) to serve as a resistor. The equivalent resistance of the transistor (MR) can be adjusted by controlling its gate voltage (Vgmr) so that it is equivalent to a variable resistor. FIG. 12(f) shows an example when an RC termination circuit (1206) uses a transistor (MR6) to serve as a resistor, and a transistor (MC6) to serve as a capacitor. The equivalent resistance of the transistor (MR6) can be adjusted by controlling its gate voltage (Vgmr6). Sometime, RC termination circuits are combined with other circuit elements. FIG. 12(g) shows an example when an RC termination circuit (1207) is connected in parallel with a resistor (RCRp) that is connected to prevent signal drifting. Strictly speaking, such a parallel resistor is not part of the RC termination circuit because its major function is not anti-reflection. An RC termination circuit can have multiple components. FIG. 12(h) shows an example RC termination circuit (1208) that comprises a network of capacitors and resistors. FIG. 12(i) shows an RC termination circuit (1209) comprising 6 transistors (MR1-MR4, MC1, MC2) and three switches (CSW1-CSW3). The first 4 transistors (MR1-MR4) of different sizes are configured as variable resistors with the overall resistance controlled by their gate voltages (Vgmr1-Vgmr4). Using 4 transistors instead of one allows wider range and better control. It also provides the option to turn off all 4 transistors (MR1-MR4) to turn off the RC termination circuit (1209). The other two transistors (MC1, MC2) and two switches (CSW1-CSW2) serve as a variable capacitors with capacitance value controlled by the states of the switches (CSW1, CSW2). A third switch (CSW3) allows the option to short the capacitors and make the RC termination circuit (1209) behave as a termination resistor.

While specific embodiments of the invention have been illustrated and described herein, it is realized that other modifications and changes will occur to those skilled in the art. It is to be understood that there are many other possible modifications and implementations so that the scope of the invention is not limited by the specific embodiments discussed herein. An RC termination circuit of the preferred embodiments of the present invention can be implemented by a combination of discrete components, integrated into packaged components, embedded in printed circuit boards, or implemented as on-chip circuits inside integrated chips. FIG. 12(j) shows a symbolic view when RC termination circuits are implemented by components external to integrated circuits. In this symbolic view, an IC chip (1220) comprises an integrated circuit (1221) that has an output driver (1222) of the present invention. For simplicity, the output driver (1220) is represented symbolically by a driver with n-channel pull up transistor and p-channel pull down transistor. This simplified symbolic view is meant to represent various output drivers of the preferred embodiments of the present invention that may have more complex structures, such as those disclosed in this patent application. This output driver drives signal on a transmission line (1226) to reach a sense circuit (1232) on another IC (1231) in another IC chip (1230). An RC termination circuit (1225) of the present invention is placed at the end of the transmission line (TL1) for anti-reflection purposes. FIG. 12(k) shows a similar configuration as FIG. 12(j) except that the RC termination circuit (1235) is implemented as an embedded component on the receiving IC (1231) that comprises the sensing circuit (1232). It is also possible to place the RC termination circuit inside the receiving IC chip (1239) but external to the receiving IC (1231). Such an embedded RC termination circuit can be placed very close to the sensing circuit (1232) for better signal quality control and cost saving.

Using the technology described herein, output drivers have been implemented on prototype integrated circuits to support DDR2 SSTL interface operations of DRAM registered dual in line memory modules (RDIMM). The prototype comprises 28 single-ended output drivers for driving DDR2 address and control signals; each output driver drives two termination circuits in a configuration illustrated by FIG. 11(g). The integrated circuit further comprises two differential output drivers for driving DDR2 clock signals; each set of differential drivers drives 5 termination circuits in a configuration similar to that illustrated by FIG. 11(i); FIG. 11(i) illustrated the configuration when fan out equals two while our prototype IC supported fan out of 5. The integrated circuit has been tested extensively on HP 93000 testers demonstrating propagation delays less than 1 nanosecond. The IC has also been placed onto hundreds of industry standard compatible RDIMM modules and tested on multiple server grade computer systems using industry standard tests. The prototype IC are fully functional in all the tests operating at DDR2 800 and DDR2 667 standards. The prototype IC confirmed that output drivers of the present invention consume little power at quiescent state even when the drivers are on. Compared with industry leading products, the prototype IC demonstrated power savings of approximately 5 to 10 milli-amperes per driver. As a summary, the expected advantages of the present invention have been demonstrated by integrated circuits that are fully functional with industry standard systems.

Output drivers of the present invention provide significant advantages over known output drivers in propagation delay time, fan out, and power consumption. Preferably, the output drivers of the present invention have a propagation delay less than 5 nanoseconds, more preferably less than 1 nanosecond, and most preferably less than 0.1 nanosecond. Preferably the output drivers of the present invention to drive one, two, four, or more termination circuits simultaneously. Preferably the output drivers of the present invention consume quiescent current less than 1000 microamperes, more preferably less than 100 microamperes, even more preferably less than 10 microamperes, and most preferable less than 1 microampere, or smaller.

While specific embodiments of the invention have been illustrated and described herein, it is realized that other modifications and changes will occur to those skilled in the art. It is therefore to be understood that the appended claims are intended to cover all modifications and changes as fall within the true spirit and scope of the invention.

1. A high performance partial voltage interface circuit comprising an integrated circuit output driver in an integrated circuit that drives high performance partial voltage output signals into one or more electrical line(s) that is (are) (a) external to the integrated circuit and (b) connected to one or more RC termination circuit(s), said output driver comprising:
a first voltage supply source;
a second voltage supply source having a lower potential than said first voltage supply source;
one or more n-channel pull up transistors electrically coupled to the electrical line(s) to the first voltage supply source, and provide a driving force to pull the electrical line(s) toward the voltage of the first voltage supply source when the one or more n-channel pull up transistors are on; and
one or more p-channel pull down transistors electrically coupled to the electrical line(s) to the second voltage supply source, and provide a driving force to drive the electrical line(s) toward the voltage of the second voltage supply source when the one or more p-channel pull down transistors are on.

2. The high performance partial voltage interface circuit of claim 1 wherein the output driver drives two or more termination circuits.

3. The high performance partial voltage interface circuit of claim 1 wherein the output driver drives four or more termination circuits.

4. The high performance partial voltage interface circuit of claim 1 wherein the output driver consumes less than 1000 micro-amperes at quiescent state.

5. The high performance partial voltage interface circuit of claim 1 wherein the output driver consumes less than 100 micro-amperes at quiescent state.

6. The high performance partial voltage interface circuit of claim 1 wherein the output driver consumes less than 10 micro-amperes at quiescent state.

7. The high performance partial voltage interface circuit of claim 1 wherein the output driver consumes less than 1 micro-ampere current at quiescent state.

8. The high performance partial voltage interface circuit of claim 1 wherein the propagation delay of the output driver is less than 5 nanoseconds.

9. The high performance partial voltage interface circuit of claim 1 wherein the propagation delay of the output driver is less than 1 nanosecond.

10. The high performance partial voltage interface circuit of claim 1 wherein the propagation delay of the output driver is less than 0.1 nanosecond.

11. The high performance partial voltage interface circuit of claim 1 wherein the output driver is coupled to an SSTL interface.

12. The high performance partial voltage interface circuit of claim 1 wherein the output driver is coupled to a GTL interface.

13. The high performance partial voltage interface circuit of claim 1 wherein the output driver is coupled to a BTL interface.

14. The high performance partial voltage interface circuit of claim 1 wherein the output driver is coupled to an SATA interface.

15. The high performance partial voltage interface circuit of claim 1 wherein the output driver is coupled to a PCIe interface.

16. The high performance partial voltage interface circuit of claim 1 wherein the output driver is coupled to an LVDS interface.

17. The high performance partial voltage interface circuit of claim 1 wherein the output driver is coupled to an MIPI interface.

18. The high performance partial voltage interface circuit of claim 1 wherein the output driver is coupled to an MDDI interface.

19. The high performance partial voltage interface circuit of claim 1 further comprising one or more depletion mode or native n-channel pull up transistor(s).

20. The high performance partial voltage interface circuit of claim 1 further comprising one or more depletion mode or native p-channel pull down transistor(s).

21. The high performance partial voltage interface circuit of claim 1 wherein the RC termination circuit is embedded in an integrated circuit.

22. A method to implement a high performance partial voltage interface circuit in an integrated circuit comprising an integrated circuit output driver that drives high performance partial voltage output signals into an external electrical line comprising the steps of:
manufacturing the integrated circuit output driver by including one or more n-channel pull up transistors and one or more p-channel pull down transistors;
connecting said integrated output driver to the electrical line external to the integrated circuit;
connecting said electrical line to one or more RC termination circuits;
coupling a first voltage supply source having a first potential to said integrated circuit output driver;
coupling a second voltage supply source having a second potential lower than the potential of the first voltage supply source to said integrated circuit output driver;
applying said one or more n-channel pull up transistors to drive said electrical line towards the first potential when said one or more n-channel pull up transistors are turned on; and
applying said one or more p-channel pull down transistors to drive said electrical line towards the second potential when said one or more p-channel pull down transistors are turned on.

23. The method in claim 22 further comprising a step of coupling the integrated circuit output driver to an SSTL interface.

24. The method in claim 22 further comprising a step of coupling the integrated circuit output driver to a GTL interface.

25. The method in claim 22 further comprising a step of coupling the integrated circuit output driver to a BTL interface.

26. The method in claim 22 further comprising a step of coupling the integrated circuit output driver to an SATA interface.

27. The method in claim 22 further comprising a step of coupling the integrated circuit output driver to a PCIe interface.

28. The method in claim 22 further comprising a step of coupling the integrated circuit output driver to an LVDS interface.

29. The method in claim 22 further comprising a step of coupling the integrated circuit output driver to an MIPI interface.

30. The method in claim 22 further comprising a step of coupling the integrated circuit output driver to an MDDI interface.

31. The method in claim 22 further comprising a step of providing depletion mode or native n-channel transistors as the one or more pull up transistors.

32. The method in claim 22 further comprising a step of providing depletion mode or native p-channel transistors as the one or more pull down transistors.

33. The method in claim 22 further comprising a step of providing an RC termination circuit within the integrated circuit.
